(19) United States
(12) Patent Application Publication
(10) Pub. No.: US 2015/0279940 A1
(43) Pub. Date: Oct. 1, 2015

(54) SILICON CARBIDE SEMICONDUCTOR DEVICE AND METHOD FOR MANUFACTURING SAME

(71) Applicant: Sumitomo Electric Industries, Ltd., Osaka-shi (JP)

(72) Inventors: Shunsuke YAMADA, Osaka-shi (JP); Yu SAITOH, Osaka-shi (JP); Takeyoshi MASUDA, Osaka-shi (JP)

(21) Appl. No.: 14/631,361

(22) Filed: Feb. 25, 2015

(30) Foreign Application Priority Data
Mar. 27, 2014 (JP) 2014-066042

(51) Int. Cl. H01L 29/10; H01L 29/66; H01L 29/78

(52) U.S. Cl. CPC H01L 29/1095; H01L 29/7827; H01L 29/78; H01L 29/66068

(57) ABSTRACT

A silicon carbide semiconductor device includes a silicon carbide substrate and an electrode. The silicon carbide substrates includes a first impurity region, a second impurity region, a third impurity region, a fourth impurity region, and an intermediate impurity region, the intermediate impurity region being interposed between the third impurity region and the fourth impurity region and having an impurity concentration that is lower than the concentration of a first conductivity type impurity in the third impurity region and that is lower than the concentration of a second conductivity type impurity in the fourth impurity region. The electrode is in contact with each of the third impurity region and the fourth impurity region on the main surface of the silicon carbide substrate. The concentration of the first conductivity type impurity in the third impurity region in contact with the electrode is not less than 5×10¹⁹ cm⁻³.

### BACKGROUND OF THE INVENTION

1. Field of the Invention

The present invention relates to a silicon carbide semiconductor device and a method for manufacturing the silicon carbide semiconductor device, particularly, a silicon carbide semiconductor device including a silicon carbide substrate having an impurity region formed therein as well as a method for manufacturing such a silicon carbide semiconductor device.

2. Description of the Background Art

In recent years, in order to achieve high breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

For example, WO2009/128382 describes a MOSFET (Metal Oxide Semiconductor Field Effect Transistor) having a source contact electrode in contact with both a p type SiC region and an n type SiC region. According to the MOSFET, the source contact electrode contains Ti, Al, and Si, thereby achieving a reduced contact resistance of the source contact electrode with respect to each of the p type SiC region and the n type SiC region.

Further, Hiroyuki Matsunami, et al., “Technology of Semiconductor SiC and Its Application, Second Edition”, Nikkan Kogyo Shinbun, Ltd., 2011, p. 301 describes that: in order to attain a contact resistivity of not more than 10⁻⁶ Ωcm⁻² on a device, doping of at least 10¹⁹ cm⁻³ is required; and when the doping is performed by means of ion implantation, doping of not less than 10²⁰ cm⁻³ is desirable in order to compensate adverse effects of decrease in activation rate and of disarrangement in crystallinity due to ion damage.

### SUMMARY OF THE INVENTION

According to the method for manufacturing the MOSFET in WO2009/128382, it was difficult to obtain an electrode having a contact resistance sufficiently low with respect to each of the n type region and the p type region.

An object of one embodiment of the present invention is to provide a silicon carbide semiconductor device and a method for manufacturing the silicon carbide semiconductor device, by each of which a contact resistance between an electrode and a p type region can be reduced while reducing a contact resistance between the electrode and an n type region.

A silicon carbide semiconductor device according to one embodiment of the present invention includes a silicon carbide substrate and an electrode. The silicon carbide substrate has a main surface. The silicon carbide substrate includes a first impurity region, a second impurity region, a third impurity region, a fourth impurity region, and an intermediate impurity region, the first impurity region having first conductivity type, the second impurity region being in contact with the first impurity region and having second conductivity type different from the first conductivity type, the third impurity region having the first conductivity type and being separated from the first impurity region by the second impurity region, the fourth impurity region having the second conductivity type and connecting the main surface and the second impurity region to each other, the intermediate impurity region being interposed between the third impurity region and the fourth impurity region and having an impurity concentration that is lower than a concentration of a first conductivity type impurity in the third impurity region and that is lower than a concentration of a second conductivity type impurity in the fourth impurity region. The electrode is in contact with each of the third impurity region and the fourth impurity region on the main surface of the silicon carbide substrate. The concentration of the first conductivity type impurity in the third impurity region in contact with the electrode is not less than 5×10¹⁹ cm⁻³.

A method for manufacturing a silicon carbide semiconductor device according to one embodiment of the present invention includes the following steps. A silicon carbide substrate having a main surface is formed. The silicon carbide substrate includes a first impurity region, a second impurity region, a third impurity region, a fourth impurity region, and an intermediate impurity region, the first impurity region having first conductivity type, the second impurity region being in contact with the first impurity region and having second conductivity type different from the first conductivity type, the third impurity region having the first conductivity type and being separated from the first impurity region by the second impurity region, the fourth impurity region having the second conductivity type and connecting the main surface and the second impurity region to each other, the intermediate impurity region being interposed between the third impurity region and the fourth impurity region and having an impurity concentration that is lower than a concentration of a first conductivity type impurity in the third impurity region and that is lower than a concentration of a second conductivity type impurity in the fourth impurity region. An electrode is formed in contact with each of the third impurity region and the fourth impurity region on the main surface of the silicon carbide substrate. The concentration of the first conductivity type impurity in the third impurity region in contact with the electrode is not less than 5×10¹⁹ cm⁻³.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view for schematically illustrating a structure of a silicon carbide semiconductor device according to a first embodiment of the present invention.

FIG. 2 shows an n type impurity concentration and a p type impurity concentration in a direction along a direction X of FIG. 1.

FIG. 3 shows an electron carrier concentration and a hole carrier concentration in the direction along direction X of FIG. 1.

FIG. 4 is an enlarged view of a region IV of FIG. 1.

FIG. 5 is a flowchart for schematically illustrating a method for manufacturing the silicon carbide semiconductor device according to the first embodiment of the present invention.

FIG. 6 is a schematic cross sectional view for schematically illustrating a first step of the method for manufacturing the silicon carbide semiconductor device according to the first embodiment of the present invention.

FIG. 7 is a schematic cross sectional view for schematically illustrating a second step of the method for manufacturing the silicon carbide semiconductor device according to the first embodiment of the present invention.

FIG. 8 is a schematic cross sectional view for schematically illustrating a third step of the method for manufacturing the silicon carbide semiconductor device according to the first embodiment of the present invention.

FIG. 9 is a schematic cross sectional view for schematically illustrating a fourth step of the method for manufacturing the silicon carbide semiconductor device according to the first embodiment of the present invention.

FIG. 10 is a schematic cross sectional view for schematically illustrating a fifth step of the method for manufacturing the silicon carbide semiconductor device according to the first embodiment of the present invention.

FIG. 11 is a schematic cross sectional view for schematically illustrating a sixth step of the method for manufacturing the silicon carbide semiconductor device according to the first embodiment of the present invention.

FIG. 12 is a schematic cross sectional view for schematically illustrating a seventh step of the method for manufacturing the silicon carbide semiconductor device according to the first embodiment of the present invention.

FIG. 13 is a schematic cross sectional view for schematically illustrating an eighth step of the method for manufacturing the silicon carbide semiconductor device according to the first embodiment of the present invention.

FIG. 14 is a schematic cross sectional view for schematically illustrating a structure of a silicon carbide semiconductor device according to a second embodiment of the present invention.

FIG. 15 shows an n type impurity concentration and a p type impurity concentration in a direction along a direction X of FIG. 14.

FIG. 16 shows an electron carrier concentration and a hole carrier concentration in the direction along direction X of FIG. 14.

FIG. 17 is a schematic cross sectional view for schematically illustrating a method for manufacturing the silicon carbide semiconductor device according to the second embodiment of the present invention.

FIG. 18 is a schematic cross sectional view for schematically illustrating a structure of a silicon carbide semiconductor device according to a third embodiment of the present invention.

FIG. 19 is a schematic cross sectional view for schematically illustrating a first step of the method for manufacturing the silicon carbide semiconductor device according to the third embodiment of the present invention.

FIG. 20 is a schematic cross sectional view for schematically illustrating a second step of the method for manufacturing the silicon carbide semiconductor device according to the third embodiment of the present invention.

FIG. 21 is a schematic cross sectional view for schematically illustrating a third step of the method for manufacturing the silicon carbide semiconductor device according to the third embodiment of the present invention.

FIG. 22 is a schematic cross sectional view for schematically illustrating a fourth step of the method for manufacturing the silicon carbide semiconductor device according to the third embodiment of the present invention.

FIG. 23 is a schematic cross sectional view for schematically illustrating a fifth step of the method for manufacturing the silicon carbide semiconductor device according to the third embodiment of the present invention.

FIG. 24 is a schematic cross sectional view for schematically illustrating a sixth step of the method for manufacturing the silicon carbide semiconductor device according to the third embodiment of the present invention.

FIG. 25 is a schematic cross sectional view for schematically illustrating a seventh step of the method for manufacturing the silicon carbide semiconductor device according to the third embodiment of the present invention.

FIG. 26 is a schematic cross sectional view for schematically illustrating an eighth step of the method for manufacturing the silicon carbide semiconductor device according to the third embodiment of the present invention.

FIG. 27 is a schematic cross sectional view for schematically illustrating a ninth step of the method for manufacturing the silicon carbide semiconductor device according to the third embodiment of the present invention.

FIG. 28 is a schematic cross sectional view for schematically illustrating a tenth step of the method for manufacturing the silicon carbide semiconductor device according to the third embodiment of the present invention.

FIG. 29 is a schematic cross sectional view for schematically illustrating a structure of a silicon carbide semiconductor device according to a fourth embodiment of the present invention.

### DESCRIPTION OF THE PREFERRED EMBODIMENTS

### Description of Embodiments of the Present Invention

The following describes embodiments of the present invention based on figures. It should be noted that in the below-mentioned figures, the same or corresponding portions are given the same reference characters and are not described repeatedly. Regarding crystallographic indications in the present specification, an individual orientation is represented by [ ], a group orientation is represented by < >, and an individual plane is represented by ( ) and a group plane is represented by { }. In addition, a negative index is supposed to be crystallographically indicated by putting “-” (bar) above a numeral, but is indicated by putting the negative sign before the numeral in the present specification.

The inventors have obtained the following knowledge and arrived at one embodiment of the present invention, as a result of diligent study about a measure of reducing a contact resistance between an n type region and an electrode while reducing a contact resistance between a p type region and the electrode.

According to the method described in WO2009/128382, an n type source region is formed in the p type body region by implanting ions of an n type impurity, such as phosphorus, for providing n type conductivity. Next, a p type contact region is formed in the n type source region in contact with the n type source region by implanting ions of a p type impurity, such as aluminum or boron, for providing p type conductivity. In order to cancel the n type polarity completely and form the p type contact region, the concentration of the n type impurity in the n type source region needs to be set lower than the concentration of the p type impurity in the p type contact region.

In contrast, an n type source region is formed in the p type contact region in contact with the p type contact region by implanting ions of the n type impurity, such as phosphorus, for providing n type conductivity. In order to cancel the p type polarity completely and form the n type source region, the concentration of the n type impurity in the n type source region needs to be set higher than the concentration of the p type impurity in the p type contact region. In other words, when the impurity concentration of a region of one conductivity type is made high, the impurity concentration of a region of the other conductivity type needs to be low, with the result that it is difficult to achieve both a high impurity concentration of the n type source region and a high impurity concentration of the p type contact region. As a result, it is difficult to obtain a source electrode having a low contact resistance with respect to both the n type source region and the p type contact region.

Moreover, in a portion in which the n type source region and the p type contact region are overlapped with each other, both the n type impurity and the p type impurity are implanted at high concentrations, resulting in large crystal disarrangement. A region having such large crystal disarrangement is likely to become a leak path, with the result that reliability may be deteriorated. Further, in a region in which the n type impurity concentration and the p type impurity concentration are comparable to each other, carriers of opposite polarities are canceled with each other, with the result that the region becomes a high resistance region.

As a result of diligent study, the inventors have found that an n type region having a high n type impurity concentration can be formed while forming a p type region having a high p type impurity concentration, by providing an intermediate impurity region between the p type region and the n type region, the intermediate impurity region being lower in impurity concentration than the concentration of the p type impurity in the p type region and being lower than the concentration of the n type impurity in the n type region. As a result, the contact resistance between the n type region and the electrode can be reduced while reducing the contact resistance between the p type region and the electrode. Moreover, by providing the intermediate impurity region between the p type region and the n type region, it is possible to suppress formation of a region in which the p type impurity and the n type impurity are implanted at high concentrations, so that crystal disarrangement can be suppressed from being large. As a result, formation of a leak path can be suppressed, thereby improving reliability of the silicon carbide semiconductor device.

(1) A silicon carbide semiconductor device 1 according to one embodiment of the present invention includes: a silicon carbide substrate 10 and an electrode 16. Silicon carbide substrate 10 has a main surface 10a. Silicon carbide substrate 10 includes a first impurity region 12, a second impurity region 13, a third impurity region 14, a fourth impurity region 18, and an intermediate impurity region 17, first impurity region 12 having first conductivity type, second impurity region 13 being in contact with the first impurity region 12 and having second conductivity type different from the first conductivity type, third impurity region 14 having the first conductivity type and being separated from first impurity region 12 by second impurity region 13, fourth impurity region 18 having the second conductivity type and connecting the main surface and second impurity region 13 to each other, intermediate impurity region 17 being interposed between third impurity region 14 and fourth impurity region 18 and having an impurity concentration that is lower than a concentration of a first conductivity type impurity in third impurity region 14 and that is lower than a concentration of a second conductivity type impurity in fourth impurity region 18. Electrode 16 is in contact with each of third impurity region 14 and fourth impurity region 18 on main surface 10a of silicon carbide substrate 10. The concentration of the first conductivity type impurity in third impurity region 14 in contact with electrode 16 is not less than 5×10¹⁹ cm⁻³.

In accordance with silicon carbide semiconductor device 1 according to (1), silicon carbide substrate 10 includes intermediate impurity region 17, intermediate impurity region 17 being interposed between third impurity region 14 and fourth impurity region 18 and having an impurity concentration that is lower than the concentration of the first conductivity type impurity in third impurity region 14 and that is lower than the concentration of the second conductivity type impurity in fourth impurity region 18. Accordingly, fourth contact region 18 containing the second conductivity type impurity at a high concentration can be formed while forming third impurity region 14 containing the first conductivity type impurity at a high concentration. As a result, the contact resistance between fourth impurity region 18 and electrode 16 can be reduced while reducing the contact resistance between third impurity region 14 and electrode 16. Moreover, it is possible to suppress formation of a region in which the first conductivity type impurity and the second conductivity type impurity are implanted at high concentrations, so that crystal disarrangement can be suppressed from being large. As a result, formation of a leak path can be suppressed, thereby improving reliability of the silicon carbide semiconductor device. Further, by setting the concentration of the first conductivity type impurity in third impurity region 14 in contact with electrode 16 at not less than 5×10¹⁹ cm⁻³, the contact resistance between electrode 16 and third impurity region 14 can be reduced effectively.

(2) Preferably in silicon carbide semiconductor device 1 according to (1), the concentration of the second conductivity type impurity in fourth impurity region 18 in contact with electrode 16 is not less than 5×10¹⁹ cm⁻³. Accordingly, the contact resistance between electrode 16 and fourth impurity region 18 can be reduced effectively.

(3) Preferably in silicon carbide semiconductor device 1 according to (1) or (2), the concentration of the first conductivity type impurity or the concentration of the second conductivity type impurity in intermediate impurity region 17 in contact with electrode 16 is not less than 1×10¹⁸ cm⁻³ and less than 5×10¹⁹ cm⁻³. Accordingly, the contact resistance between electrode 16 and intermediate impurity region 17 can be reduced effectively.

(4) Preferably in the silicon carbide semiconductor device according to any one of (1) to (3), electrode 16 contains at least one of Ti, Al and Ni. Accordingly, the contact resistance between silicon carbide substrate 10 and electrode 16 can be reduced effectively.

(5) Preferably in the silicon carbide semiconductor device according to (4), electrode 16 contains TiAlSi. Accordingly, ohmic contact can be attained between electrode 16 and the first conductivity type region, and ohmic contact can be attained between electrode 16 and the second conductivity type region.

(6) Preferably in the silicon carbide semiconductor device according to any one of (1) to (5), the first conductivity type is n type, and the second conductivity type is p type. Accordingly, high channel mobility can be obtained.

(7) Preferably in the silicon carbide semiconductor device according to any one of (1) to (6), intermediate impurity region 17 constitutes a portion of second impurity region 13. Accordingly, intermediate impurity region 17 and second impurity region 13 can be formed simultaneously, thereby simplifying the process.

(8) Preferably in the silicon carbide semiconductor device according to any one of (1) to (7), main surface 10a of silicon carbide substrate 10 corresponds to a silicon plane or a plane off by 8° or less relative to the silicon plane, and the silicon carbide semiconductor device includes a planar type MOSFET. In this way, the breakdown voltage of the silicon carbide semiconductor device can be improved.

(9) Preferably in the silicon carbide semiconductor device according to any one of (1) to (7), main surface 10a of silicon carbide substrate 10 corresponds to a carbon plane or a plane off by 8° or less relative to the carbon plane, and the silicon carbide semiconductor device includes a trench type MOSFET. Accordingly, the on-resistance of the silicon carbide semiconductor device can be reduced.

(10) A method for manufacturing a silicon carbide semiconductor device according to one embodiment of the present invention includes the following steps. A silicon carbide substrate 10 having a main surface 10a is formed. Silicon carbide substrate 10 includes a first impurity region 12, a second impurity region 13, a third impurity region 14, a fourth impurity region 18, and an intermediate impurity region 17, first impurity region 12 having first conductivity type, second impurity region 13 being in contact with first impurity region 12 and having second conductivity type different from the first conductivity type, third impurity region 14 having the first conductivity type and being separated from first impurity region 12 by second impurity region 13, fourth impurity region 18 having the second conductivity type and connecting main surface 10a and second impurity region 13 to each other, intermediate impurity region 17 being interposed between third impurity region 14 and fourth impurity region 18 and having an impurity concentration that is lower than a concentration of a first conductivity type impurity in third impurity region 14 and that is lower than a concentration of a second conductivity type impurity in fourth impurity region 18. An electrode 16 is formed in contact with each of third impurity region 14 and fourth impurity region 18 on main surface 10a of silicon carbide substrate 10. The concentration of the first conductivity type impurity in third impurity region 14 in contact with electrode 16 is not less than 5×10¹⁹ cm⁻³.

In accordance with the method for manufacturing the silicon carbide semiconductor device according to (10), fourth impurity region 18 containing the second conductivity type impurity at a high concentration can be formed while forming third impurity region 14 containing the first conductivity type impurity at a high concentration. As a result, the contact resistance between fourth impurity region 18 and electrode 16 can be reduced while reducing the contact resistance between third impurity region 14 and electrode 16. Moreover, it is possible to suppress formation of a region in which the first conductivity type impurity and the second conductivity type impurity are implanted at high concentrations, so that crystal disarrangement can be suppressed from being large. As a result, formation of a leak path can be suppressed, thereby improving reliability of the silicon carbide semiconductor device. Further, by setting the concentration of the first conductivity type impurity in third impurity region 14 in contact with electrode 16 at not less than 5×10¹⁹ cm⁻³, the contact resistance between electrode 16 and third impurity region 14 can be reduced effectively.

(11) Preferably in the method for manufacturing the silicon carbide semiconductor device according to (10), the step of forming silicon carbide substrate 10 includes the steps of: forming first impurity region 12; forming second impurity region 13 by introducing the second conductivity type impurity into first impurity region 12; forming intermediate impurity region 17 by introducing the first conductivity type impurity or the second conductivity type impurity into second impurity region 13; forming fourth impurity region 18 by introducing the second conductivity type impurity into intermediate impurity region 17; and forming third impurity region 14 by introducing the first conductivity type impurity into intermediate impurity region 17. Accordingly, fourth contact region 18 containing the second conductivity type impurity at a high concentration can be formed while forming third impurity region 14 containing the first conductivity type impurity at a high concentration, effectively.

(12) Preferably in the method for manufacturing the silicon carbide semiconductor device according to (10), the step of forming silicon carbide substrate 10 includes the steps of: forming first impurity region 12; forming second impurity region 13 by introducing the second conductivity type impurity into first impurity region 12; and forming each of third impurity region 14 and fourth impurity region 18 such that third impurity region 14 is separated from fourth impurity region 18, by introducing the first conductivity type impurity and the second conductivity type impurity into second impurity region 13, and intermediate impurity region 17 constitutes a portion of second impurity region 13. Accordingly, the intermediate impurity region and the second impurity region can be formed simultaneously, thereby simplifying the process.

(13) Preferably in the method for manufacturing the silicon carbide semiconductor device according to any one of (10) to (12), each of third impurity region 14 and fourth impurity region 18 is formed by ion implantation. This increases both the concentration of the first conductivity type impurity in third impurity region 14 and the concentration of the second conductivity type impurity in fourth impurity region 18. As a result, the contact resistance between fourth impurity region 18 and electrode 16 can be reduced while reducing the contact resistance between third impurity region 14 and electrode 16, effectively.

(14) Preferably in the method for manufacturing the silicon carbide semiconductor device according to any one of (10) to (13), the concentration of the second conductivity type impurity in fourth impurity region 18 in contact with electrode 16 is not less than 5×10¹⁹ cm⁻³. Accordingly, the contact resistance between electrode 16 and fourth impurity region 18 can be reduced effectively.

(15) Preferably in the method for manufacturing the silicon carbide semiconductor device according to any one of (10) to (14), the concentration of the first conductivity type impurity or the concentration of the second conductivity type impurity in intermediate impurity region 17 in contact with electrode 16 is not less than 1×10¹⁸ cm⁻³ and less than 5×10¹⁹ cm⁻³. Accordingly, the contact resistance between electrode 16 and intermediate impurity region 17 can be reduced effectively.

(16) Preferably in the method for manufacturing the silicon carbide semiconductor device according to any one of (10) to (15), electrode 16 contains at least one of Ti, Al and Ni. Accordingly, the contact resistance between silicon carbide substrate 10 and electrode 16 can be reduced effectively.

(17) Preferably in the method for manufacturing the silicon carbide semiconductor device according to (16), electrode 16 contains TiAlSi. Accordingly, ohmic contact can be attained between electrode 16 and the first conductivity type region, and ohmic contact can be attained between electrode 16 and the second conductivity type region.

(18) Preferably in the method for manufacturing the silicon carbide semiconductor device according to any one of (10) to (17), the first conductivity type is n type and the second conductivity type is p type. Accordingly, high channel mobility can be obtained.

(19) Preferably in the method for manufacturing the silicon carbide semiconductor device according to any one of (10) to (18), main surface 10a of silicon carbide substrate 10 corresponds to a silicon plane or a plane off by 8° or less relative to the silicon plane, and the silicon carbide semiconductor device includes a planar type MOSFET. In this way, the breakdown voltage of the silicon carbide semiconductor device can be improved.

(20) Preferably in the method for manufacturing the silicon carbide semiconductor device according to any one of (10) to (18), main surface 10a of silicon carbide substrate 10 corresponds to a carbon plane or a plane off by 8° or less relative to the carbon plane, and the silicon carbide semiconductor device includes a trench type MOSFET. Accordingly, the on-resistance of the silicon carbide semiconductor device can be reduced.

### Details of Embodiments of the Present Invention

### First Embodiment

First, the following describes a configuration of a planar type MOSFET serving as a silicon carbide semiconductor device according to a first embodiment of the present invention.

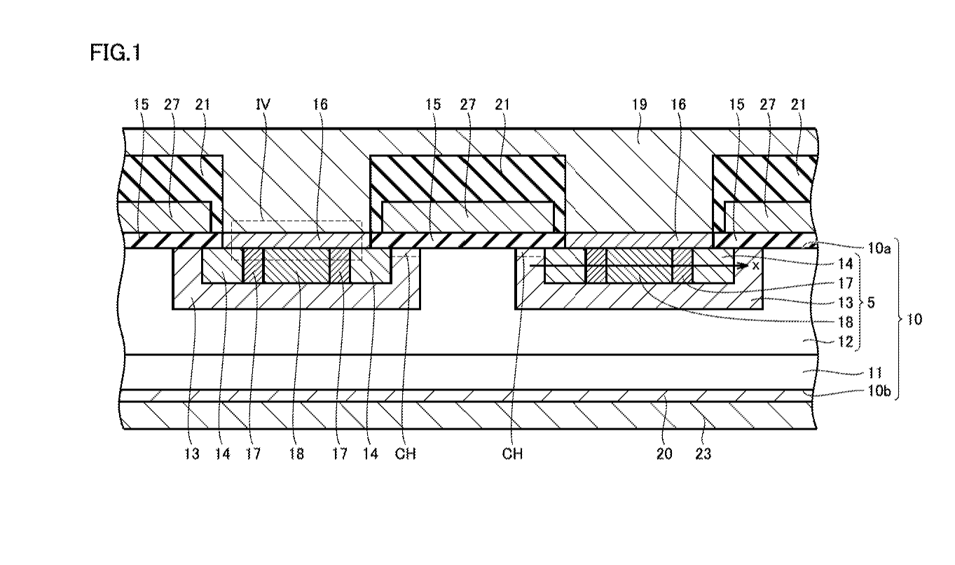

With reference to FIG. 1, planar type MOSFET 1 according to the present embodiment mainly includes a silicon carbide substrate 10, a gate electrode 27, a gate oxide film 15, an interlayer insulating film 21, a source electrode 16, a front surface protecting electrode 19, a drain electrode 20, and a backside surface protecting electrode 23. Silicon carbide substrate 10 has a first main surface 10a and a second main surface 10b opposite to first main surface 10a, and mainly includes a silicon carbide single crystal substrate 11 and a silicon carbide epitaxial layer 5 provided on a silicon carbide single crystal substrate 11.

Silicon carbide single crystal substrate 11 is made of, for example, hexagonal silicon carbide single crystal of polytype 4H. First main surface 10a of silicon carbide substrate 10 has a maximum diameter of, for example, more than 100 mm, preferably, not less than 150 mm. First main surface 10a of silicon carbide substrate 10 corresponds to a {0001} plane or a plane off by 8° or less relative to the {0001} plane, for example. Specifically, first main surface 10a corresponds to a (0001) plane (Si plane) or a plane off by about 8° or less relative to the (0001) plane (Si plane), whereas second main surface 10b corresponds to a (000-1) plane (C plane) or a plane off by about 8° or less relative to the (000-1) plane (C plane), for example. Silicon carbide substrate 10 has a thickness of, for example, not more than 700 μm, preferably, not more than 500 μm.

Silicon carbide epitaxial layer 5 has a drift region 12, a body region 13, a source region 14, an intermediate impurity region 17, and a contact region 1a. Drift region 12 (first impurity region 12) is an n type (first conductivity type) region containing an n type impurity (donor), such as nitrogen, for providing n type conductivity. The concentration of the n type impurity in drift region 12 is about 5.0×10¹⁵ cm⁻³, for example. The concentration of the n type impurity in drift region 12 is lower than the concentration of the n type impurity in silicon carbide single crystal substrate 11. Body region 13 (second impurity region 13) is a region having p type (second conductivity type) conductivity, which is different from n type conductivity. Body region 13 contains a p type impurity (acceptor), such as Al (aluminum) or B (boron), for providing p type conductivity, for example. The concentration of the p type impurity in body region 13 is about 1×10¹⁷ cm⁻³, for example.

Source region 14 (third impurity region 14) is an n type region containing an n type impurity such as phosphorus. Source region 14 is formed in body region 13 to be surrounded by body region 13. The concentration of the n type impurity in source region 14 is higher than the concentration of the n type impurity in drift region 12. The concentration of the n type impurity, such as phosphorus, in source region 14 is 1×10²⁰ cm⁻³, for example. Source region 14 is separated from drift region 12 by body region 13.

Intermediate impurity region 17 is provided between source region 14 and contact region 18 so as to connect first main surface 10a of silicon carbide substrate 10 and body region 13 to each other. Intermediate impurity region 17 contains an n type impurity such as nitrogen, and has n type conductivity. The concentration of the n type impurity such as phosphorus in intermediate impurity region 17 is 1×10²⁰ cm⁻³, for example. Intermediate impurity region 17 may contain a p type impurity such as aluminum or boron, and may have p type conductivity, for example. When intermediate impurity region 17 has p type conductivity, the concentration of the p type impurity such as aluminum in intermediate impurity region 17 is 3×10¹⁹ cm⁻³, for example. That is, when intermediate impurity region 17 has n type conductivity, the concentration of the n type impurity in intermediate impurity region 17 is lower than the concentration of the n type impurity in source region 14 and is lower than the concentration of the p type impurity in contact region 18. Meanwhile, when intermediate impurity region 17 has p type conductivity, the concentration of the p type impurity in intermediate impurity region 17 is lower than the concentration of the n type impurity in source region 14 and is lower than the concentration of the p type impurity in contact region 18. Preferably, intermediate impurity region 17 has a width of not less than 0.1 μm in a direction parallel to first main surface 10a of silicon carbide substrate 10.

Contact region 18 (fourth impurity region 18) is a p type region containing a p type impurity such as aluminum or boron. Contact region 18 is provided to be surrounded by intermediate impurity region 17, and is formed to connect first main surface 10a of silicon carbide substrate 10 and body region 13 to each other. The concentration of the p type impurity in contact region 18 is higher than the concentration of the p type impurity in body region 13. The concentration of the p type impurity such as aluminum in contact region 18 is 1×10²⁰ cm⁻³, for example. Preferably, the concentration of the p type impurity such as aluminum in contact region 18 is not less than 2×10²⁰ cm⁻³, and the concentration of the n type impurity, such as phosphorus, in source region 14 is not less than 5×10¹⁹ cm⁻³. The element and concentration of the impurity in each of the regions can be measured using an SCN (Scanning Capacitance Microscope), an SIMS (Secondary Ion Mass Spectrometry), or the like, for example.

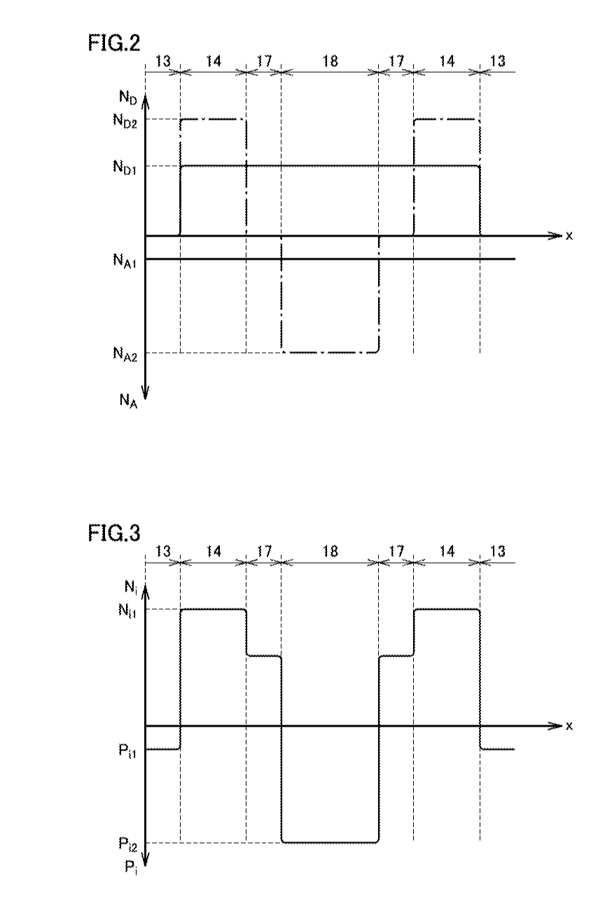

With reference to FIG. 2 and FIG. 3, the following describes the impurity concentrations in body region 13, source region 14, intermediate impurity region 17, and contact region 18. The x direction in each of FIG. 2 and FIG. 3 corresponds to the x direction shown in FIG. 1. The upper side of the y axis in FIG. 2 represents the concentration of the first conductivity type impurity (n type impurity), whereas the lower side of the y axis represents the concentration of the second conductivity type impurity (p type impurity). The upper side of the y axis in FIG. 3 represents the concentration of carriers (electrons) exhibiting n type conductivity, whereas the lower side of the y axis represents the concentration of carriers (holes) exhibiting the p type conductivity. The y axis in each of FIG. 2 and FIG. 3 is illustrated in log scale.

As shown in FIG. 2, each of body region 13, source region 14, intermediate impurity region 17, and contact region 18 contains a first p type impurity such as aluminum, for example. The concentration of the first p type impurity in each of body region 13, source region 14, and intermediate impurity region 17 is a first p type impurity concentration N_{A1}. In addition to the first p type impurity, contact region 18 contains a second p type impurity such as aluminum, for example. The second p type impurity concentration in the contact region is a second p type impurity concentration N_{A2}. Second p type impurity concentration N_{A2} is higher than first p type impurity concentration N_{A1}.

Each of source region 14, intermediate impurity region 17, and contact region 18 contains a first n type impurity such as phosphorus, for example. The concentration of the first n type impurity in each of source region 14, intermediate impurity region 17, and contact region 18 is a first n type impurity concentration N_{D1}. In addition to the first n type impurity, source region 14 contains a second n type impurity such as phosphorus, for example. The concentration of the second n type impurity in source region 14 is a second n type impurity concentration N_{D2}. Second n type impurity concentration N_{D2} is higher than first n type impurity concentration N_{D1}.

That is, source region 14 contains the first p type impurity, the first n type impurity, and the second n type impurity. Intermediate impurity region 17 contains the first p type impurity and the first n type impurity. Contact region 18 contains the first p type impurity, the second p type impurity, and the first n type impurity. It should be noted that the first p type impurity may be the same as the second p type impurity. Moreover, the first n type impurity may be the same as the second n type impurity. As shown in FIG. 2, the concentration of the n type impurity (first conductivity type impurity) in intermediate impurity region 17 is lower than the concentration of the n type impurity (first conductivity type impurity) in source region 14, and is lower than the concentration of the p type impurity (second conductivity type impurity) in contact region 18.

With reference to FIG. 3, in source region 14, the n type impurity concentration becomes higher than the p type impurity concentration, with the result that the electron becomes a majority carrier. In intermediate impurity region 17, the n type impurity concentration is higher than the p type impurity concentration, so that the electron becomes a majority carrier. Moreover, in intermediate impurity region 17, the p type impurity concentration may become higher than the n type impurity concentration, with the result that the hole may become a majority carrier. In contact region 18, the p type impurity concentration is higher than the n type impurity concentration, so that the hole becomes a majority carrier. That is, each of body region 13 and contact region 18 has p type conductivity, and each of intermediate impurity region 17 and source region 14 exhibits n type conductivity. It should be noted that when the hole is a majority carrier in intermediate impurity region 17, intermediate impurity region 17 exhibits p type conductivity.

With reference to FIG. 1 again, source electrode 16 is disposed in contact with first main surface 10a of silicon carbide substrate 10 such that source electrode 16 is in contact with gate oxide film 15 and extends from above source region 14 to above contact region 18 via above intermediate impurity region 17. Source electrode 16 is in contact with each of source region 14 and contact region 18 on first main surface 10a of silicon carbide substrate 10. Source electrode 16 may be in contact with intermediate impurity region 17. The concentration of the n type impurity in source region 14 in contact with source electrode 16 is not less than 5×10¹⁹ cm⁻³. Preferably, the concentration of the p type impurity in contact region 18 in contact with source electrode 16 is not less than 5×10¹⁹ cm⁻³. Preferably, the concentration of the n type impurity or the p type impurity in intermediate impurity region 17 in contact with source electrode 16 is not less than 1×10¹⁸ cm⁻³ and is less than 5×10¹⁹ cm⁻³. Preferably, the contact resistance between source region 14 and source electrode 16 is not more than 1×10⁻⁴ Ωcm², and the contact resistance between contact region 18 and source electrode 16 is not more than 1×10⁻⁴ Ωcm².

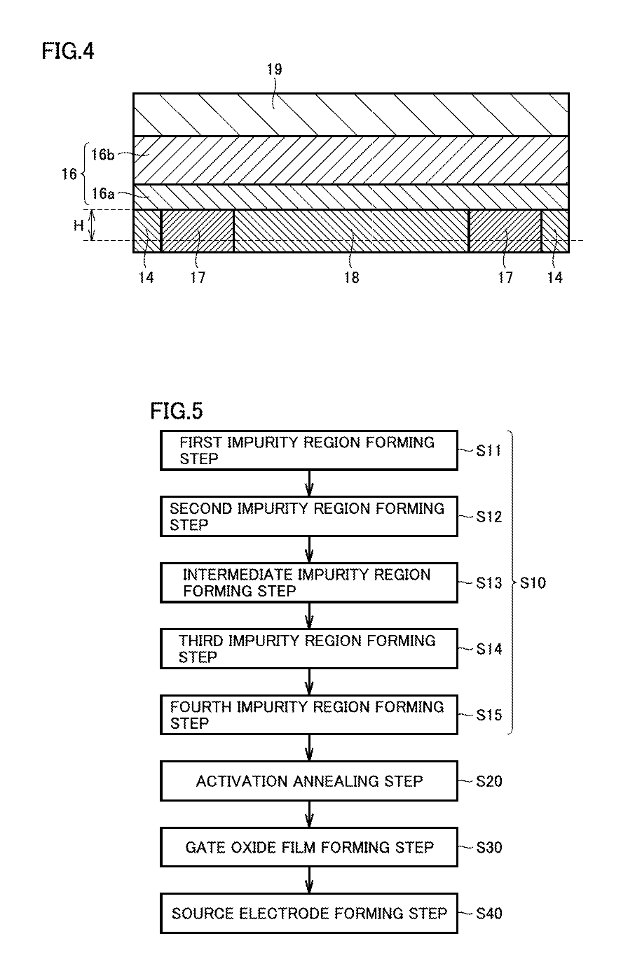

With reference to FIG. 4, source electrode 16 includes an alloy layer 16a and a metal layer 16b. Alloy layer 16a is silicide of a metal contained in source electrode 16, for example. Metal layer 16b is provided on alloy layer 16a. The concentration of the n type impurity in source region 14 in contact with source electrode 16 refers to the concentration of the n type impurity in a region from a boundary between alloy layer 16a and source region 14 to a depth H that is in the direction of second main surface 10b. Depth H is typically of several ten nm, such as 50 nm. The same applies to the impurity concentration of contact region 18 in contact with source electrode 16 and the impurity concentration in intermediate impurity region 17 in contact with source electrode 16. Preferably, source electrode 16 contains at least one of Ti, Al and Ni. Source electrode 16 is made of a material containing, for example, TiAlSi, TiAl, TiSi, NiSi, NiAl, Ni, or the like. Preferably, source electrode 16 is made of a material containing TiAlSi. Source electrode 16 is in ohmic junction with source region 14 via alloy layer 16a. Preferably, source electrode 16 is in ohmic junction with each of intermediate impurity region 17 and contact region 18 via alloy layer 16a.

Gate oxide film 15 is formed in contact with first main surface 10a of silicon carbide substrate 10 so as to extend from the upper surface of one source region 14 to the upper surface of the other source region 14. Gate oxide film 15 is in contact with source region 14, body region 13, and drift region 12 on first main surface 10a of silicon carbide substrate 10. Gate oxide film 15 is configured such that a channel region CH can be formed at a portion of body region 13 that is in contact with gate oxide film 15. Gate oxide film 15 is made of, for example, silicon dioxide. Gate oxide film 15 has a thickness of, for example, about not less than 40 nm and not more than 60 nm.

Gate electrode 27 is disposed in contact with gate oxide film 15 so as to extend from above one source region 14 to above the other source region 14. Gate electrode 27 is provided on gate oxide film 15 such that gate oxide film 15 is interposed between gate electrode 27 and silicon carbide substrate 10. Gate electrode 27 is formed above source region 14, body region 13, and drift region 12 with gate oxide film 15 being interposed therebetween. Gate electrode 27 is made of a conductor such as polysilicon having an impurity doped therein or Al, for example.

Interlayer insulating film 21 is provided at a position facing first main surface 10a of silicon carbide substrate 10. Specifically, interlayer insulating film 21 is provided in contact with each of gate electrode 27 and gate oxide film 15 so as to cover gate electrode 27. Interlayer insulating film 21 electrically insulates between gate electrode 27 and source electrode 16. Front surface protecting electrode 19 is provided in contact with source electrode 16 so as to cover interlayer insulating film 21. Front surface protecting electrode 19 is electrically connected to source region 14 via source electrode 16.

Drain electrode 20 is provided in contact with second main surface 10b of silicon carbide substrate 10. This drain electrode 20 is made of a material capable of ohmic junction with n type silicon carbide single crystal substrate 11, such as NiSi (nickel silicide). Accordingly, drain electrode 20 is electrically connected to silicon carbide single crystal substrate 11. Backside surface protecting electrode 23 is formed in contact with the main surface of drain electrode 20 opposite to silicon carbide single crystal substrate 11. Backside surface protecting electrode 23 is made of a material containing Al, for example.

The following describes an operation of MOSFET 1 according to the first embodiment. With reference to FIG. 1, when a voltage is applied between source electrode 16 and drain electrode 20 while an applied voltage to gate electrode 27 is lower than a threshold voltage, i.e., while it is in OFF state, a pn junction formed between body region 13 and drift region 12 is reverse-biased. Accordingly, MOSFET 1 is in the non-conductive state. On the other hand, when gate electrode 27 is fed with a voltage equal to or greater than the threshold voltage, an inversion layer is formed in channel region CH near a location at which body region 13 makes contact with gate oxide film 15. As a result, source region 14 and drift region 12 are electrically connected to each other, whereby a current flows between source electrode 16 and drain electrode 20. In the manner described above, MOSFET 1 operates.

Next, the following describes a method for manufacturing MOSFET 1 serving as the silicon carbide semiconductor device according to the first embodiment.

First, a silicon carbide substrate preparing step (S10: FIG. 5) is performed. The silicon carbide substrate preparing step (S10: FIG. 5) includes a first impurity region forming step (S11: FIG. 5), a second impurity region forming step (S12: FIG. 5), an intermediate impurity region forming step (S13: FIG. 5), a third impurity region forming step (S14: FIG. 5), and a fourth impurity region forming step (S15: FIG. 5).

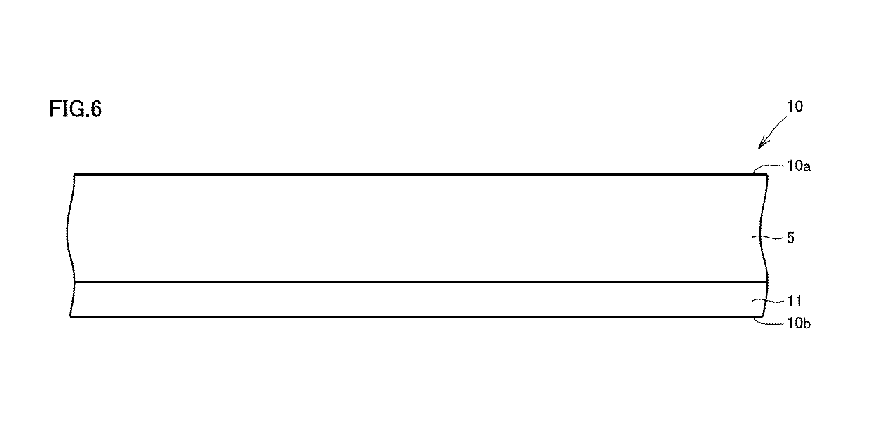

First, the first impurity region forming step (S11: FIG. 5) is performed. For example, silicon carbide single crystal substrate 11 is prepared by slicing an ingot made of hexagonal silicon carbide single crystal having polytype 4H and formed through a sublimation method. Next, silicon carbide epitaxial layer 5 is formed on silicon carbide single crystal substrate 11 by a CVD (Chemical Vapor Deposition) method, for example. Specifically, silicon carbide single crystal substrate 11 is supplied with a carrier gas containing hydrogen (H₂) and a source material gas containing mono silane (SiH₄), propane (C₃H₈), nitrogen (N₂) and the like, and silicon carbide single crystal substrate 11 is heated at about not less than 1500° C. and not more than 1700° C., for example. Accordingly, as shown in FIG. 6, silicon carbide epitaxial layer 5 is formed on silicon carbide single crystal substrate 11. In this way, silicon carbide substrate 10 is prepared which has first main surface 10a and second main surface 10b opposite to first main surface 10a. First main surface 10a of silicon carbide substrate 10 corresponds to a (0001) plane (Si plane) or a plane off by about 8° or less relative to the (0001) plane (Si plane), for example. Silicon carbide substrate 10 includes: silicon carbide single crystal substrate 11 that forms second main surface 10b; and silicon carbide epitaxial layer 5 provided on silicon carbide single crystal substrate 11 to form first main surface 10a. Each of silicon carbide single crystal substrate 11 and silicon carbide epitaxial layer 5 has an n type impurity such as nitrogen, for example. Silicon carbide epitaxial layer 5 includes drift region 12 having n type conductivity (first conductivity type).

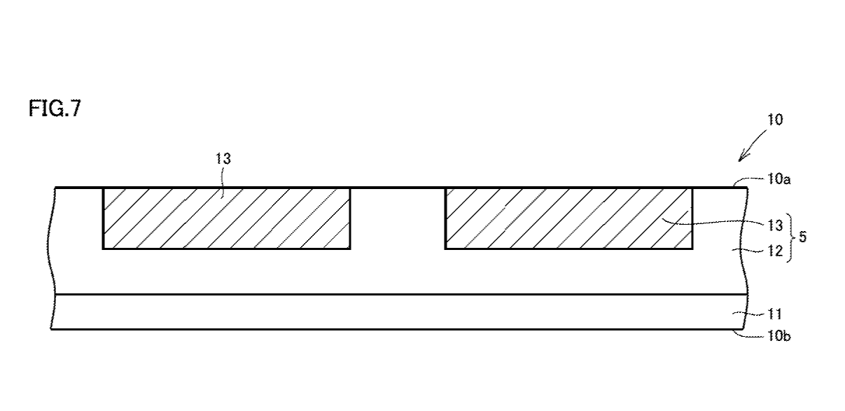

Next, the second impurity region forming step (S12: FIG. 5) is performed. Specifically, with reference to FIG. 7, ion implantation is performed into first main surface 10a of silicon carbide substrate 10. For example, Al (aluminum) ions are implanted into first main surface 10a of silicon carbide substrate 10, thereby forming body region 13 having p type conductivity (second conductivity type) in silicon carbide epitaxial layer 5. Body region 13 is a region containing a p type impurity such as aluminum. In silicon carbide epitaxial layer 5, a region other than body region 13 will serve as drift region 12. In other words, silicon carbide epitaxial layer 5 includes drift region 12 and the body region in contact with drift region 12. As described above, by introducing the p type impurity into drift region 12, body region 13 serving as second impurity region 13 is formed.

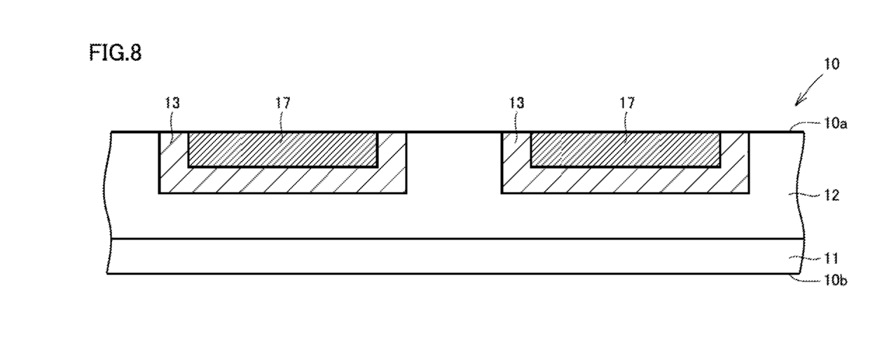

Next, the intermediate impurity region forming step (S13: FIG. 5) is performed. With reference to FIG. 8, P (phosphorus) ions are introduced into body region 13 up to a depth shallower than the depth of body region 13, thereby forming intermediate impurity region 17 having n type conductivity, for example. Intermediate impurity region 17 is a region containing an n type impurity such as phosphorus, for example. The concentration of the n type impurity (phosphorus) in intermediate impurity region 17 is higher than the concentration of the p type impurity (aluminum) in intermediate impurity region 17. The upper surface of intermediate impurity region 17 is in contact with first main surface 10a of silicon carbide substrate 10, and the side surface and lower surface of intermediate impurity region 17 are in contact with body region 13. Intermediate impurity region 17 is formed to be separated away from drift region 12 by body region 13. It should be noted that intermediate impurity region 17 having p type conductivity may be formed by implanting aluminum ions into body region 13 up to a depth shallower than the depth of body region 13, for example. In this case, intermediate impurity region 17 is a region containing a p type impurity such as aluminum, for example. As described above, intermediate impurity region 17 is framed by introducing the n type impurity or the p type impurity into body region 13.

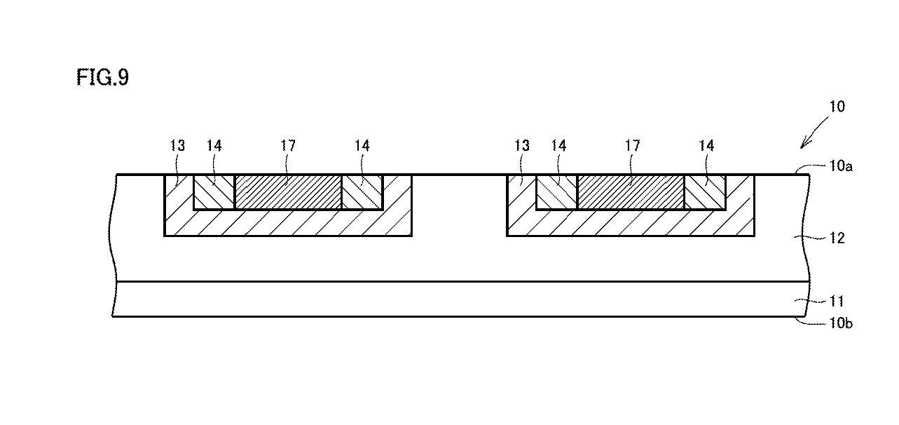

Next, the third impurity region forming step (S14: FIG. 5) is performed. With reference to FIG. 9, P (phosphorus) ions are implanted into intermediate impurity region 17 up to a depth as deep as the depth of intermediate impurity region 17, thereby forming source region 14 having n type conductivity (see FIG. 9), for example. Source region 14 is an n type region containing an n type impurity such as phosphorus, for example. The concentration of the n type impurity (phosphorus) in the source region is higher than the concentration of the p type impurity (aluminum). The upper surface of source region 14 is in contact with first main surface 10a of silicon carbide substrate 10, the side surface of source region 14 is in contact with body region 13 and intermediate impurity region 17, and the lower surface of source region 14 is in contact with body region 13. Source region 14 is formed to be separated away from drift region 12 by body region 13. It should be noted that when intermediate impurity region 17 has n type conductivity, the concentration of the n type impurity in source region 14 is higher than the concentration of the n type impurity in intermediate impurity region 17. When intermediate impurity region 17 has p type conductivity, the concentration of the n type impurity in source region 14 is higher than the concentration of the p type impurity in intermediate impurity region 17. As described above, by introducing the n type impurity into intermediate impurity region 17, source region 14 serving as third impurity region 14 is formed.

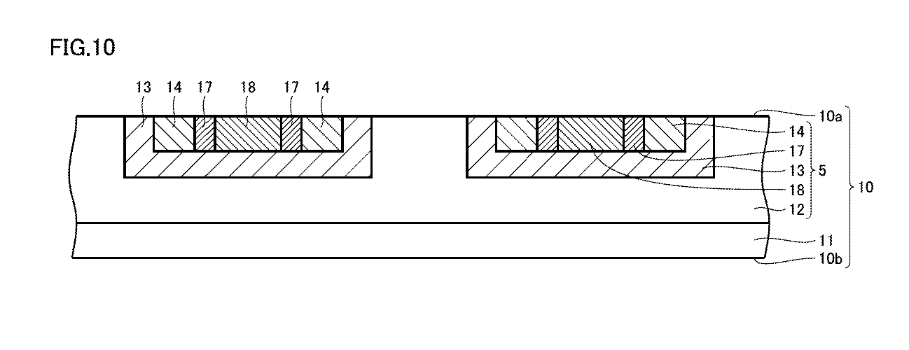

Next, the fourth impurity region forming step (S15: FIG. 5) is performed. Next, aluminum ions are further implanted into intermediate impurity region 17 up to a depth as deep as source region 14 and shallower than body region 13, for example. Accordingly, contact region 18 is formed which is surrounded by source region 14, extends from first main surface 10a to body region 13 in the normal direction of first main surface 10a of silicon carbide substrate 10, and has p type conductivity (see FIG. 10). Contact region 18 is an impurity region containing a p type impurity such as aluminum, for example. Contact region 18 is formed to be separated from source region 14 by intermediate impurity region 17 and body region 13. As described above, by introducing the p type impurity into intermediate impurity region 17, contact region 18 serving as fourth impurity region 18 is formed. Accordingly, there is prepared silicon carbide substrate 10 including: drift region 12 having n type conductivity; body region 13 in contact with drift region 12 and having p type conductivity; source region 14 having n type conductivity and separated from drift region 12 by body region 13; contact region 18 having p type conductivity and connecting first main surface 10a and body region 13 to each other; and intermediate impurity region 17 interposed between source region 14 and contact region 18 and having an impurity concentration lower than the concentration of the n type impurity in source region 14 and lower than the concentration of the p type impurity in contact region 18. Although it has been illustrated that contact region 18 is formed after source region 14 is formed, source region 14 may be formed after contact region 18 is formed.

Preferably, each of source region 14 and contact region 18 is formed through ion implantation. Each of body region 13 and intermediate impurity region 17 may be formed through ion implantation or epitaxial growth.

Next, an activation annealing step (S20: FIG. 5) is performed. Specifically, silicon carbide substrate 10 including body region 13, source region 14, intermediate impurity region 17, and contact region 18 is heated for 30 minutes at a temperature of, for example, about not less than 1600° C. and not more than 2000° C. This leads to activation of the p type impurity in body region 13, the n type impurity in source region 14, the p type impurity or n type impurity in intermediate impurity region 17, and the p type impurity in contact region 18.

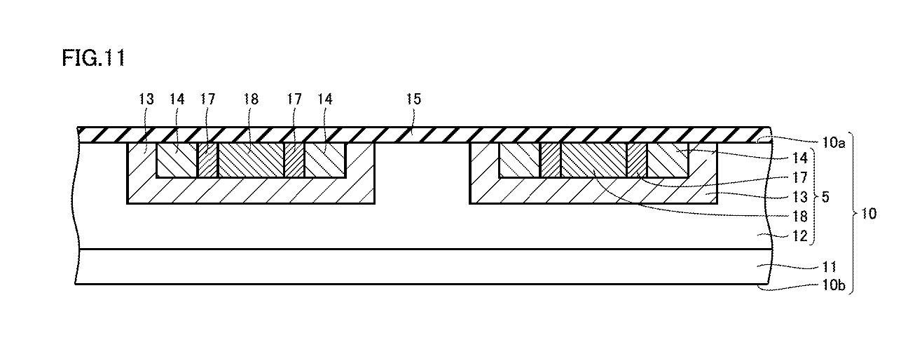

Next, a gate oxide film forming step (S30: FIG. 5) is performed. Specifically, silicon carbide substrate 10 is placed in a heating furnace, silicon carbide substrate 10 including body region 13, source region 14, intermediate impurity region 17, and contact region 18, which are formed at the first main surface 10a side of silicon carbide substrate 10. While maintaining a state in which nitrogen gas is introduced into the heating furnace, the temperature of silicon carbide substrate 10 is heated from a room temperature to 1300° C. After silicon carbide substrate 10 reaches 1300° C., oxygen gas is introduced into the heating furnace. Silicon carbide substrate 10 is held in the oxygen atmosphere at a temperature of about 1300° C. for about 1 hour, thereby forming gate oxide film 15 on first main surface 10a of silicon carbide substrate 10. In the manner described above, gate oxide film 15 made of silicon dioxide is formed to cover first main surface 10a of silicon carbide substrate 10 (see FIG. 11). Gate oxide film 15 is formed in contact with drift region 12, body region 13, source region 14, intermediate impurity region 17, and contact region 18 on first main surface 10a of silicon carbide substrate 10. Gate oxide film 15 has a thickness of, for example, about 50 nm.

Next, a NO annealing step is performed. Specifically, silicon carbide substrate 10 having gate oxide film 15 formed thereon is heated at a temperature of about 1300° C. in an atmosphere containing nitrogen. Examples of the gas containing nitrogen include nitrogen monoxide (NO), dinitrogen oxide, nitrogen dioxide, ammonia, and the like. Preferably, silicon carbide substrate 10 having gate oxide film 15 formed thereon is held for about 1 hour in a gas containing nitrogen at a temperature of not less than 1300° C. and not more than 1500° C., for example.

Next, an Ar annealing step is performed. Specifically, in an inert gas atmosphere such as argon, silicon carbide substrate 10 having gate oxide film 15 formed thereon is heated at a temperature of about 1300° C. Preferably, in the argon gas, silicon carbide substrate 10 having gate oxide film 15 formed thereon is held for about 1 hour at a temperature of, for example, not less than 1100° C. and not more than 1500° C. More preferably, silicon carbide substrate 10 having gate oxide film 15 formed thereon is held at a temperature of not less than 1300° C. and not more than 1500° C.

Next, a gate electrode forming step is performed. Through an LPCVD (Low Pressure Chemical Vapor Deposition) method, gate electrode 27 made of polysilicon containing an impurity is formed on gate oxide film 15, for example. Gate electrode 27 is formed to face drift region 12, source region 14, and body region 13 with gate oxide film 15 being interposed therebetween.

Next, an interlayer insulating film forming step is performed. Interlayer insulating film 21 made of silicon dioxide is formed to cover gate oxide film 15 and gate electrode 27, for example. Specifically, TEOS (Tetraethylorthosilicate) gas is supplied onto silicon carbide substrate 10 for about 6 hours at a temperature of about not less than 650° C. and not more than 750° C., for example. Accordingly, interlayer insulating film 21 is formed to cover gate oxide film 15 and gate electrode 27.

Next, an etching step is performed. With reference to FIG. 12, in a region in which source electrode 16 is to be formed, portions of interlayer insulating film 21 and gate oxide film 15 are removed. Preferably, interlayer insulating film 21 and gate oxide film 15 are etched such that each of source region 14, intermediate impurity region 17, and contact region 18 is exposed from interlayer insulating film 21 and gate oxide film 15. CF₄ can be used as an etching gas.

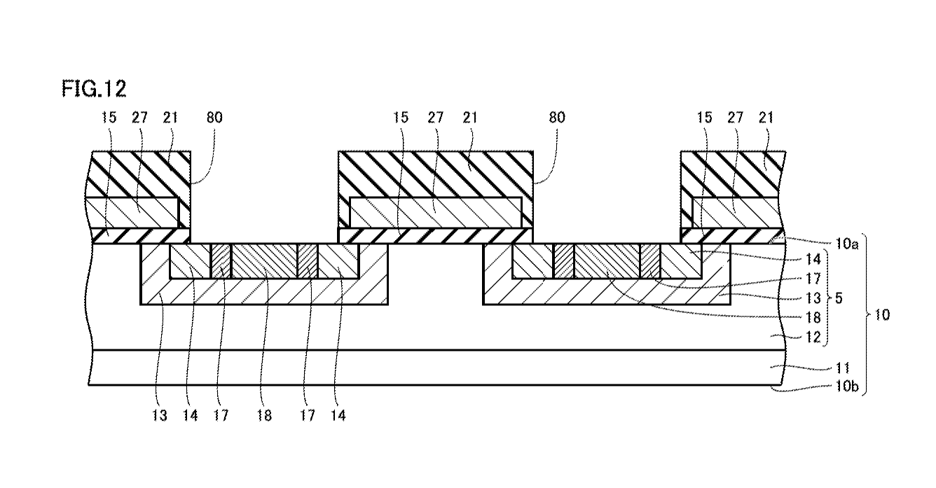

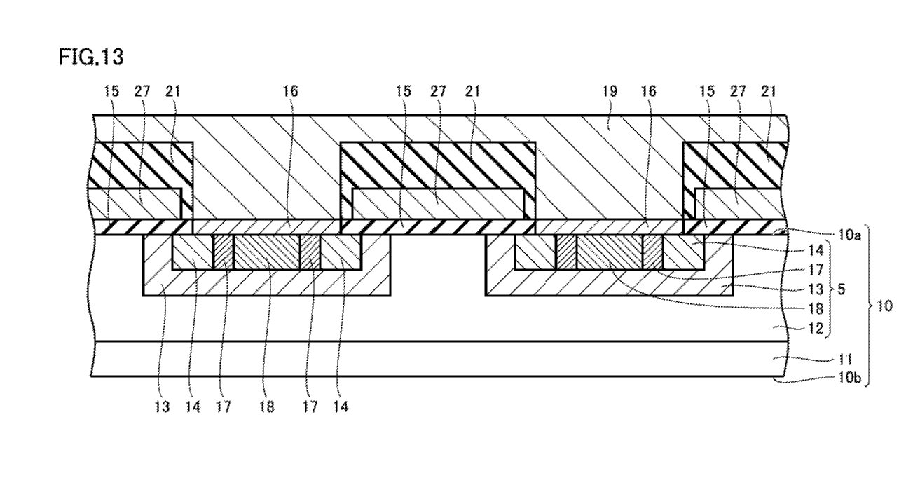

Next, a source electrode forming step (S40: FIG. 7) is performed. With reference to FIG. 13, source electrode 16 is formed in opening 80 in contact with each of source region 14 and contact region 18 on first main surface 10a of silicon carbide substrate 10. Source electrode 16 may be in contact with intermediate impurity region 17 on first main surface 10a of silicon carbide substrate 10. Preferably, source electrode 16 contains at least one of Ti, Al and Ni. Preferably, source electrode 16 is made of a material containing TiAlSi. Source electrode 16 is formed by a sputtering method, for example. Next, silicon carbide substrate 10 having the source electrode formed in contact with each of source region 14, intermediate impurity region 17, and contact region 18 on first main surface 10a of silicon carbide substrate 10 is heated for about 5 minutes at not less than 900° C. and not more than 1100° C., for example. Accordingly, at least a portion of source electrode 16 reacts with silicon in the silicon carbide substrate to result in silicidation, thereby forming alloy layer 16a (see FIG. 4). In this way, source electrode 16 including alloy layer 16a in ohmic junction with source region 14 is formed. Preferably, source electrode 16 includes alloy layer 16a in ohmic junction with each of intermediate impurity region 17 and contact region 18.

The concentration of the n type impurity in source region 14 in contact with source electrode 16 is not less than 5×10¹⁹ cm⁻³. Preferably, the concentration of the p type impurity (aluminum) in contact region 18 in contact with source electrode 16 is not less than 5×10¹⁹ cm⁻³. Preferably, the concentration of the n type impurity (phosphorus) or p type impurity (aluminum) in intermediate impurity region 17 in contact with source electrode 16 is not less than 1×10¹⁸ cm⁻³ and not more than 5×10¹⁹ cm⁻³.

Next, front surface protecting electrode 19 is formed in contact with source electrode 16 to cover interlayer insulating film 21. Front surface protecting electrode 19 is preferably made of a material containing Al, such as AlSiCu. After the formation of front surface protecting electrode 19, a lamp annealing step may be performed. In the lamp annealing step, silicon carbide substrate 10 provided with front surface protecting electrode 19 is heated for about 30 seconds at a temperature of not less than 700° C. and not more than 800° C., for example.

Next, drain electrode 20 made of, for example, NiSi is formed in contact with second main surface 10b of silicon carbide substrate 10. Drain electrode 20 may be TiAlSi or the like, for example. Drain electrode 20 is preferably formed by the sputtering method, but may be formed by vapor deposition. After drain electrode 20 is formed, drain electrode 20 is heated by laser annealing, for example. Accordingly, at least a portion of drain electrode 20 is silicided, thereby forming drain electrode 20 in ohmic junction with silicon carbide single crystal substrate 11. Next, backside surface protecting electrode 23 is formed in contact with drain electrode 20. Backside surface protecting electrode 23 is made of a material containing Al, for example. In the manner described above, MOSFET 1 shown in FIG. 1 is manufactured.

Next, the following describes function and effect of planar type MOSFET 1 serving as the silicon carbide semiconductor device according to the first embodiment as well as the method for manufacturing such a MOSFET 1.

In accordance with planar type MOSFET 1 according to the first embodiment, silicon carbide substrate 10 includes intermediate impurity region 17 that is interposed between source region 14 and contact region 18 and that has an impurity concentration lower than the concentration of the n type impurity in source region 14 and lower than the concentration of the p type impurity in contact region 18. Accordingly, contact region 18 containing the p type impurity at a high concentration can be formed while forming source region 14 containing the n type impurity at a high concentration. As a result, the contact resistance between contact region 18 and source electrode 16 can be reduced while reducing the contact resistance between source region 14 and source electrode 16. Moreover, it is possible to suppress formation of a region in which the n type impurity and the p type impurity are implanted at high concentrations, so that crystal disarrangement can be suppressed from being large. As a result, formation of a leak path can be suppressed, thereby improving reliability of MOSFET 1. Further, by setting the concentration of the n impurity in source region 14 in contact with source electrode 16 at not less than 5×10¹⁹ cm⁻³, the contact resistance between source electrode 16 and source region 14 can be reduced effectively.

Moreover, in accordance with planar type MOSFET 1 according to the first embodiment, the concentration of the p type impurity in contact region 18 in contact with source electrode 16 is not less than 5×10¹⁹ cm⁻³. Accordingly, the contact resistance between source electrode 16 and contact region 18 can be reduced effectively.

Further, in accordance with planar type MOSFET 1 according to the first embodiment, the concentration of the n type impurity or the concentration of the p type impurity in intermediate impurity region 17 in contact with source electrode 16 is not less than 1×10¹⁸ cm⁻³ and less than 5×10¹⁹ cm⁻³. Accordingly, the contact resistance between source electrode 16 and intermediate impurity region 17 can be reduced effectively.

Further, in accordance with planar type MOSFET 1 according to the first embodiment, source electrode 16 contains at least one of Ti, Al and Ni. Accordingly, the contact resistance between silicon carbide substrate 10 and source electrode 16 can be reduced effectively.

Further, in accordance with planar type MOSFET 1 according to the first embodiment, source electrode 16 contains TiAlSi. Accordingly, ohmic contact can be attained between source electrode 16 and the n type region, and ohmic contact can be attained between source electrode 16 and the p type region.

Further, in accordance with planar type MOSFET 1 according to the first embodiment, the first conductivity type is n type, and the second conductivity type is p type. Accordingly, high channel mobility can be obtained.

Further, in accordance with planar type MOSFET 1 according to the first embodiment, main surface 10a of silicon carbide substrate 10 corresponds to a silicon plane or a plane off by 8° or less relative to the silicon plane. In this way, the breakdown voltage of the silicon carbide semiconductor device can be improved.

In accordance with the method for manufacturing planar type MOSFET 1 according to the first embodiment, contact region 18 containing the p type impurity at a high concentration can be formed while forming source region 14 containing the n type impurity at a high concentration. As a result, the contact resistance between contact region 18 and source electrode 16 can be reduced while reducing the contact resistance between source region 14 and source electrode 16. Moreover, it is possible to suppress formation of a region in which the n type impurity and the p type impurity are implanted at high concentrations, so that crystal disarrangement can be suppressed from being large. As a result, formation of a leak path can be suppressed, thereby improving reliability of MOSFET 1. Further, by setting the concentration of the n impurity in source region 14 in contact with source electrode 16 at not less than 5×10¹⁹ cm⁻³, the contact resistance between source electrode 16 and source region 14 can be reduced effectively.

Further, in accordance with the method for manufacturing planar type MOSFET 1 according to the first embodiment, the step of fat ing silicon carbide substrate 10 includes the steps of: forming drift region 12; forming body region 13 by introducing a p type impurity into drift region 12; forming intermediate impurity region 17 by introducing an n type impurity or a p type impurity into body region 13; forming contact region 18 by introducing a p type impurity into intermediate impurity region 17; and forming source region 14 by introducing an n type impurity into intermediate impurity region 17. Accordingly, contact region 18 containing the p type impurity at a high concentration can be formed while forming source region 14 containing the n type impurity at a high concentration, effectively.

Further, in accordance with the method for manufacturing planar type MOSFET 1 according to the first embodiment, each of source region 14 and contact region 18 is formed by ion implantation. Accordingly, both the concentration of the n type impurity in source region 14 and the concentration of the p type impurity in contact region 18 can be increased. As a result, the contact resistance between contact region 18 and source electrode 16 can be reduced while reducing the contact resistance between source region 14 and source electrode 16, effectively.

Further, in accordance with the method for manufacturing planar type MOSFET 1 according to the first embodiment, the concentration of the p type impurity in contact region 18 in contact with source electrode 16 is not less than 5×10¹⁹ cm⁻³. Accordingly, the contact resistance between source electrode 16 and contact region 18 can be reduced effectively.

Further, in accordance with the method for manufacturing planar type MOSFET 1 according to the first embodiment, the concentration of the n type impurity or the concentration of the p type impurity in intermediate impurity region 17 in contact with source electrode 16 is not less than 1×10¹⁸ cm⁻³ and less than 5×10¹⁹ cm⁻³. Accordingly, the contact resistance between source electrode 16 and intermediate impurity region 17 can be reduced effectively.

Further, in accordance with the method for manufacturing planar type MOSFET 1 according to the first embodiment, source electrode 16 contains at least one of Ti, Al and Ni. Accordingly, the contact resistance between silicon carbide substrate 10 and source electrode 16 can be reduced effectively.

Further, in accordance with the method for manufacturing planar type MOSFET 1 according to the first embodiment, source electrode 16 contains TiAlSi. Accordingly, ohmic contact can be attained between source electrode 16 and the n type region, and ohmic contact can be attained between source electrode 16 and the p type region.

Further, in accordance with the method for manufacturing planar type MOSFET 1 according to the first embodiment, the first conductivity type is n type, and the second conductivity type is p type. Accordingly, high channel mobility can be obtained.

Further, in accordance with the method for manufacturing planar type MOSFET 1 according to the first embodiment, main surface 10a of silicon carbide substrate 10 corresponds to a silicon plane or a plane off by 8° or less relative to the silicon plane. In this way, the breakdown voltage of the silicon carbide semiconductor device can be improved.

### Second Embodiment

Next, the following describes a configuration of a planar type MOSFET serving as a silicon carbide semiconductor device according to a second embodiment of the present invention. The planar type MOSFET according to the second embodiment is different from the planar type MOSFET according to the first embodiment in that intermediate impurity region 17 constitutes a portion of the second impurity region, and is the same as the planar type MOSFET according to the first embodiment in terms of other configurations. Hence, the same or corresponding portions are given the same reference characters and are not described repeatedly.

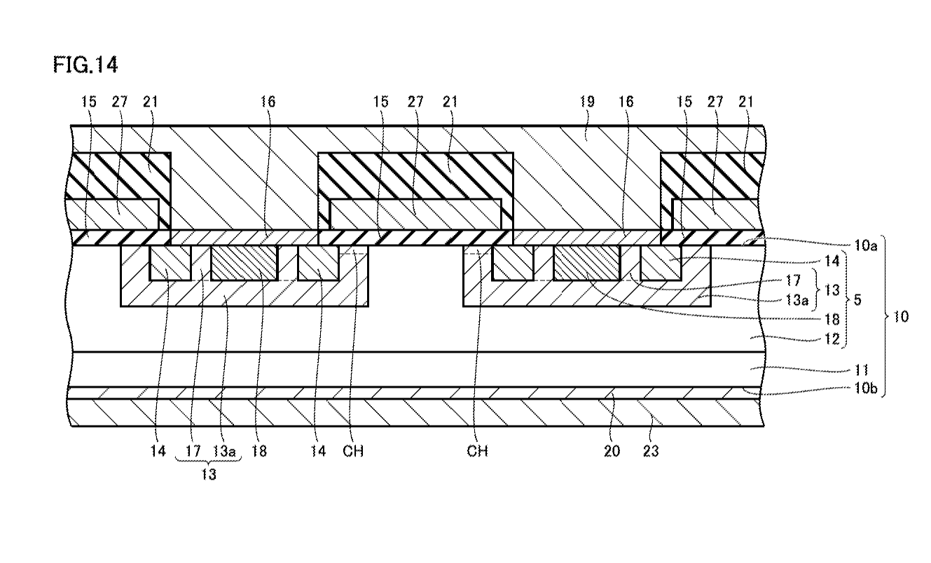

With reference to FIG. 14, intermediate impurity region 17 between source region 14 and contact region 18 constitutes a portion of body region 13. In other words, body region 13 includes: intermediate impurity region 17 in contact with source electrode 16 on first main surface 10a of silicon carbide substrate 10; and a body region portion 13a continuously connected to intermediate impurity region 17. Body region portion 13a is in contact with each of contact region 18 and source region 14.

As shown in FIG. 15, each of body region portion 13a, source region 14, intermediate impurity region 17, and contact region 18 contains a p type impurity (first p type impurity) such as aluminum, for example. The concentration of the p type impurity (second p type impurity) in intermediate impurity region 17 is comparable to the concentration of the p type impurity (second p type impurity) in body region portion 13a. The concentration of the first p type impurity in each of body region portion 13a, source region 14, and intermediate impurity region 17 is a first p type impurity concentration N_{A1}. In addition to the first p type impurity, contact region 18 contains a second p type impurity. The second p type impurity concentration in the contact region is a second p type impurity concentration N_{A2}. Second p type impurity concentration N_{A2} is higher than first p type impurity concentration N_{A1}.

Source region 14 contains the first n type impurity. The concentration of the first n type impurity in source region 14 is a first n type impurity concentration N_{D1}. That is, source region 14 contains the first p type impurity and the first n type impurity. As shown in FIG. 15, the concentration of the p type impurity in intermediate impurity region 17 is lower than the concentration of the p type impurity in contact region 18 and is lower than the concentration of the n type impurity in source region 14.

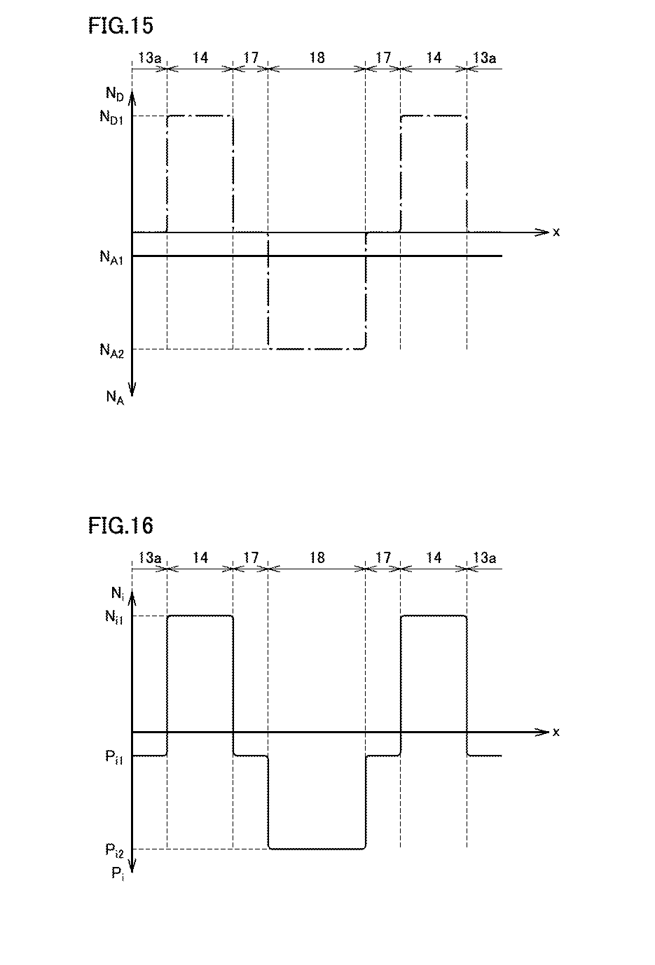

With reference to FIG. 16, in source region 14, the n type impurity concentration becomes higher than the p type impurity concentration, with the result that the electron becomes a majority carrier. In intermediate impurity region 17, the p type impurity concentration becomes higher than the n type impurity concentration, with the result that the hole becomes a majority carrier. In contact region 18, the p type impurity concentration is higher than the n type impurity concentration, with the result that the hole becomes a majority carrier. That is, each of body region portion 13a, intermediate impurity region 17, and contact region 18 has p type conductivity, and source region 14 exhibits n type conductivity. Body region portion 13a and intermediate impurity region 17 form body region 13.

Next, the following describes a method for manufacturing the planar type MOSFET according to the second embodiment. The method for manufacturing the planar type MOSFET according to the second embodiment is different from the method for manufacturing the planar type MOSFET according to the first embodiment in terms of the step of forming silicon carbide substrate 10, and is the same as the method for manufacturing the planar type MOSFET according to the first embodiment in terms of the other configurations.

Specifically, the first impurity region forming step (S11: FIG. 5) described in the first embodiment is performed, thereby forming drift region 12. Next, the second impurity region forming step (S12: FIG. 5) is performed, thereby forming body region 13 in drift region 12.

Next, the third impurity region forming step (S14: FIG. 5) is performed. For example, P (phosphorus) ions are implanted into body region 13 up to a depth shallower than body region 13, thereby forming source region 14 having n type conductivity. Source region 14 is a region containing the n type impurity, such as phosphorus, for example. The concentration of the n type impurity (phosphorus) in the source region is higher than the concentration of the p type impurity (aluminum). Source region 14 is formed to be separated from drift region 12 by body region 13.

Next, the fourth impurity region forming step (S15: FIG. 5) is performed. Next, for example, aluminum ions are further implanted into body region 13 up to a depth as deep as source region 14 and shallower than body region 13. Accordingly, contact region 18 is formed which is provided to be separated from source region 14, extends in the normal direction of first main surface 10a of silicon carbide substrate 10, and has p type conductivity (see FIG. 17). Contact region 18 contains a p type impurity such as aluminum, for example. Contact region 18 is formed to be separated from source region 14 by intermediate impurity region 17 constituting a portion of body region 13. As described above, by introducing the n type impurity such as phosphorus and the p type impurity such as aluminum into body region 13, each of source region 14 and contact region 18 is formed such that source region 14 is separated from contact region 18. Although it has been illustrated that contact region 18 is formed after source region 14 is formed, source region 14 may be formed after contact region 18 is formed.

Next, the following describes function and effect of planar type MOSFET 1 serving as the silicon carbide semiconductor device according to the second embodiment as well as the method for manufacturing such a MOSFET 1.

In accordance with the method for manufacturing planar type MOSFET 1 according to the second embodiment, intermediate impurity region 17 constitutes a portion of body region 13. Accordingly, intermediate impurity region 17 and body region 13 can be formed simultaneously, thereby simplifying the process.

In accordance with the method for manufacturing planar type MOSFET 1 according to the second embodiment, the step of forming silicon carbide substrate 10 includes the steps of: forming drift region 12; forming body region 13 by introducing the p type impurity into drift region 12; and forming each of source region 14 and contact region 18 such that source region 14 is separated from contact region 18, by introducing an n type impurity and a p type impurity into body region 13, and intermediate impurity region 17 constitutes a portion of body region 13. Accordingly, intermediate impurity region 17 and body region 13 can be formed simultaneously, thereby simplifying the process.

### Third Embodiment

Next, the following describes a configuration of a trench type MOSFET serving as a silicon carbide semiconductor device according to a third embodiment of the present invention.

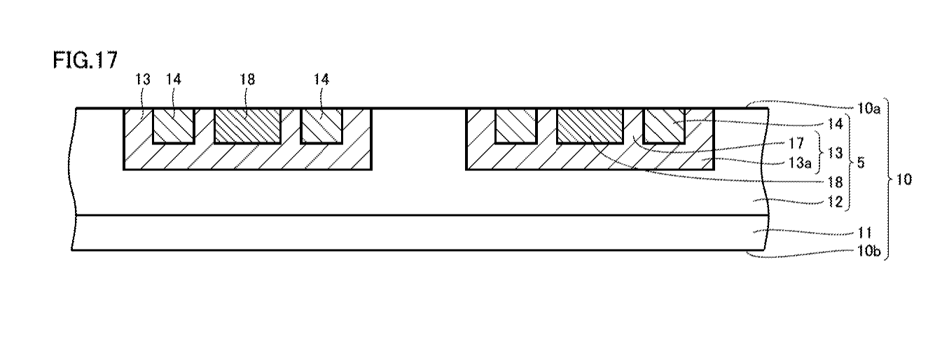

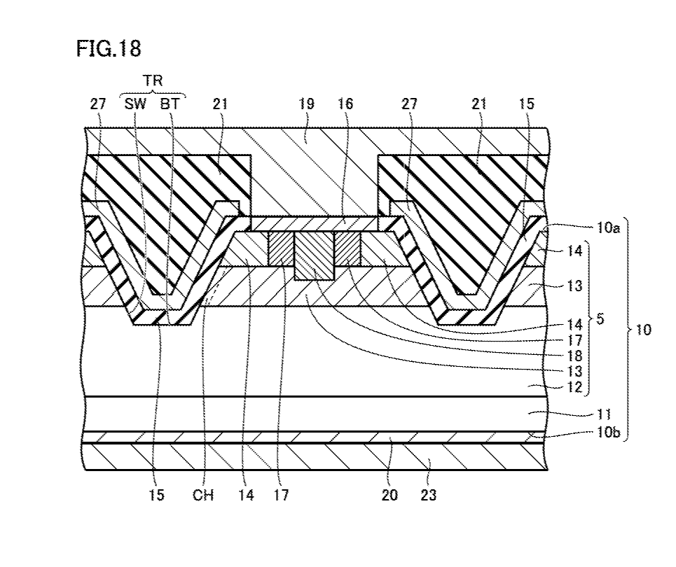

With reference to FIG. 18, MOSFET 1 serving as the silicon carbide semiconductor device according to the third embodiment mainly includes a silicon carbide substrate 10, a gate oxide film 15, a gate electrode 27, an interlayer insulating film 21, a source electrode 16, a front surface protecting electrode 19, a drain electrode 20, and a backside surface protecting electrode 23.

Silicon carbide substrate 10 has a first main surface 10a and a second main surface 10b opposite to first main surface 10a. Silicon carbide substrate 10 includes a silicon carbide single crystal substrate 11 and a silicon carbide epitaxial layer 5 provided on silicon carbide single crystal substrate 11. Silicon carbide single crystal substrate 11 has a hexagonal crystal structure of polytype 4H, for example. Silicon carbide single crystal substrate 11 contains an impurity such as nitrogen and has n type conductivity (first conductivity type), for example.

First main surface 10a of silicon carbide substrate 10 has a maximum diameter of more than 100 mm, preferably, not less than 150 mm, for example. First main surface 10a of silicon carbide substrate 10 corresponds to a {000-1} plane or a plane off by 8° or less relative to the {000-1} plane, for example. Specifically, for example, first main surface 10a corresponds to a (000-1) plane (C plane) or a plane off by about 8° or less relative to the (000-1) plane (C plane), whereas second main surface 10b corresponds to a (0001) plane (Si plane) or a plane off by about 8° or less relative to the (0001) plane (Si plane). Silicon carbide substrate 10 has a thickness of, for example, not more than 700 μm, preferably, not more than 500 μm.

Silicon carbide epitaxial layer 5 of silicon carbide substrate 10 mainly includes drift region 12, body region 13, source region 14, contact region 18, and intermediate impurity region 17. Drift region 12 (first impurity region 12) is an n type region containing an n type impurity such as nitrogen. The concentration of the n type impurity in drift region 12 is about 5.0×10¹⁵ cm⁻³, for example. The concentration of the n type impurity in drift region 12 is lower than the concentration of the n type impurity in silicon carbide single crystal substrate 11. Body region 13 (second impurity region 13) is a region having p type conductivity. Body region 13 includes a p type impurity such as Al (aluminum) or B (boron), for example. The concentration of the p type impurity in body region 13 is about 1×10¹⁷ cm⁻³, for example.

Source region 14 (third impurity region 14) is an n type region containing an n type impurity such as phosphorus. Source region 14 is formed on body region 13. The concentration of the n type impurity in source region 14 is higher than the concentration of the n type impurity in drift region 12. The concentration of the n type impurity, such as phosphorus, in source region 14 is 1×10²⁰ cm⁻³, for example. Source region 14 is separated from drift region 12 by body region 13.

Intermediate impurity region 17 is provided between source region 14 and contact region 18 so as to connect first main surface 10a of silicon carbide substrate 10 and body region 13 to each other. Intermediate impurity region 17 contains an n type impurity such as nitrogen, and has n type conductivity. The concentration of the n type impurity such as phosphorus in intermediate impurity region 17 is 1×10²⁰ cm⁻³, for example. Intermediate impurity region 17 may contain a p type impurity such as aluminum or boron, and may have p type conductivity, for example. When intermediate impurity region 17 has p type conductivity, the concentration of the p type impurity such as aluminum in intermediate impurity region 17 is 3×10¹⁹ cm⁻³, for example. That is, when intermediate impurity region 17 has n type conductivity, the concentration of the n type impurity in intermediate impurity region 17 is lower than the concentration of the n type impurity in source region 14 and is lower than the concentration of the p type impurity in contact region 18. Further, when intermediate impurity region 17 has p type conductivity, the concentration of the p type impurity in intermediate impurity region 17 is lower than the concentration of the n type impurity in source region 14 and is lower than the concentration of the p type impurity in contact region 18.

Contact region 18 (fourth impurity region 18) is a p type region containing a p type impurity such as aluminum or boron. Contact region 18 is provided to be surrounded by intermediate impurity region 17, and is formed to connect first main surface 10a of silicon carbide substrate 10 and body region 13 to each other. The concentration of the p type impurity in contact region 18 is higher than the concentration of the p type impurity in body region 13. The concentration of the p type impurity such as aluminum in contact region 18 is 1×10²⁰ cm⁻³, for example. Preferably, the concentration of the p type impurity such as aluminum in contact region 18 is not less than 2×10²⁰ cm⁻³, and the concentration of the n type impurity such as phosphorus in source region 14 is not less than 5×10¹⁹ cm⁻³. The depth of contact region 18 in the normal direction of first main surface 10a of silicon carbide substrate 10 may be deeper than the depth of each of intermediate impurity region 17 and source region 14.

With reference to FIG. 18, a trench TR is provided in first main surface 10a of silicon carbide substrate 10. Trench TR includes: a side portion SW extending to drift region 12 through source region 14 and body region 13; and a bottom portion BT continuously connected to side portion SW and located in drift region 12. In other words, each of drift region 12, body region 13, and source region 14 is in contact with side portion SW of trench TR. Drift region 12 is in contact with each of bottom portion BT and side portion SW of trench TR.

Side portion SW of trench TR is inclined relative to first main surface 10a of silicon carbide substrate 10, whereby trench TR extends in a tapered manner toward the opening. First main surface 10a of silicon carbide substrate 10 corresponds to the {000-1} plane, for example. Side portion SW of trench TR is inclined relative to first main surface 10a by 62°, for example. Side portion SW of trench TR preferably has a plane orientation inclined relative to the (000-1) plane by not less than 50° and not more than 70°. Preferably, side portion SW of trench TR is inclined relative to bottom portion BT by not less than 50° and not more than 70°. Bottom portion BT of trench TR is substantially parallel to each of first main surface 10a and second main surface 10b of silicon carbide substrate 10.

Gate oxide film 15 is provided in contact with bottom portion BT of trench TR, side portion SW of trench TR, and first main surface 10a of silicon carbide substrate 10. Gate oxide film 15 is in contact with source region 14 on each of first main surface 10a of silicon carbide substrate 10 and side portion SW of trench TR, is in contact with body region 13 on side portion SW of trench TR, and is in contact with drift region 12 on each of side portion SW and bottom portion BT of the trench. Gate oxide film 15 is made of for example, silicon dioxide.

Gate electrode 27 is in contact with gate oxide film 15 in trench TR. Specifically, gate electrode 27 is provided to face each of source region 14, body region 13, and drift region 12 with gate oxide film 15 being interposed therebetween. Gate electrode 27 is made of a material containing polysilicon having an impurity doped therein, for example.

Interlayer insulating film 21 and gate oxide film 15 are provided with an opening formed to expose contact region 18, source region 14, and intermediate impurity region 17 on first main surface 10a of silicon carbide substrate 10. Source electrode 16 is in contact with each of source region 14, intermediate impurity region 17, and contact region 18 on first main surface 10a of silicon carbide substrate 10. Front surface protecting electrode 19 is provided on and in contact with source electrode 16, and is electrically connected to source electrode 16. Front surface protecting electrode 19 is a layer containing aluminum, for example. Source electrode 16 is made of the same material as the material described in the first embodiment.

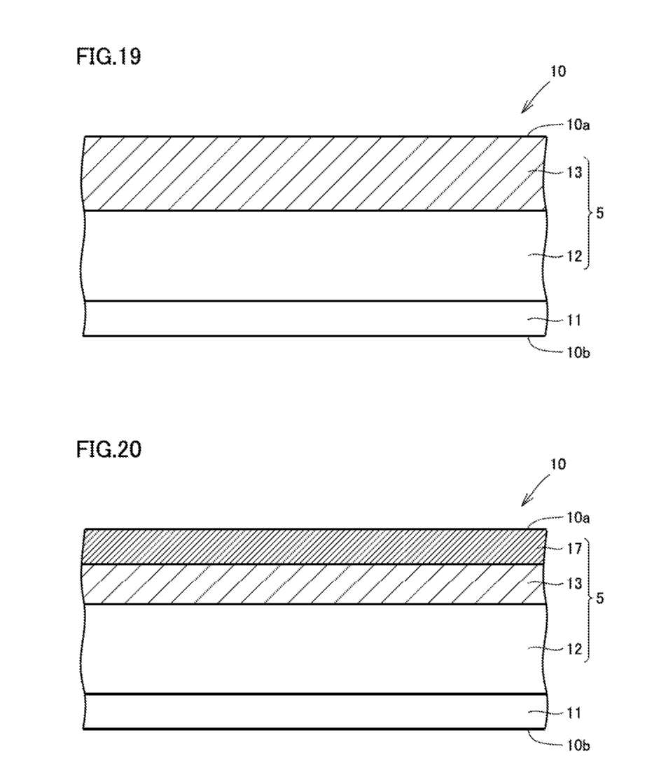

Next, with reference to FIG. 19 to FIG. 28, the following describes a method for manufacturing trench type MOSFET 1, which is the silicon carbide semiconductor device according to the third embodiment.

First, a silicon carbide substrate preparing step is performed. Silicon carbide epitaxial layer 5 is formed on silicon carbide single crystal substrate 11. Specifically, silicon carbide epitaxial layer 5 is formed using a CVD method that utilizes a mixed gas of silane (SiH₄) and propane (C₃H₈) as a material gas and utilizes hydrogen gas (H₂) as a carrier gas, for example. During epitaxial growth, an impurity, such as nitrogen (N), is introduced into silicon carbide epitaxial layer 5, for example. In this way, silicon carbide substrate 10 is prepared which has silicon carbide epitaxial layer 5 formed on silicon carbide single crystal substrate 11. First main surface 10a of silicon carbide substrate 10 corresponds to a (000-1) plane (C plane) or a plane off by about 8° or less relative to the (000-1) plane (C plane), for example.

Next, an ion implantation step is performed. With reference to FIG. 19, for example, ions of a p type impurity such as aluminum are implanted into drift region 12, thereby forming body region 13 in contact with drift region 12. Next, with reference to FIG. 20, for example, ions of an n type impurity such as phosphorus are implanted into the body region, thereby forming intermediate impurity region 17 provided on body region 13. It should be noted that body region 13 and intermediate impurity region 17 may be formed by epitaxial growth involving addition of an impurity instead of the ion implantation.

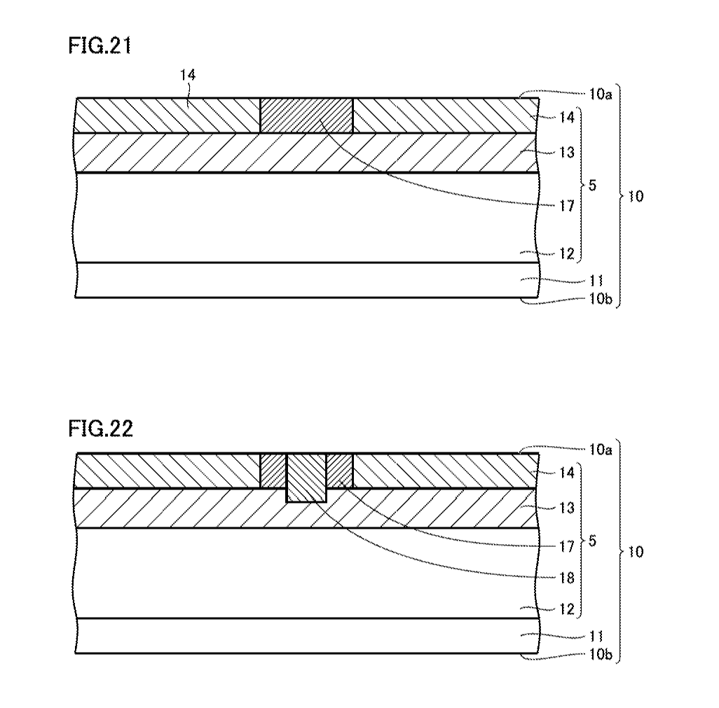

Next, for example, the ions of the n type impurity such as phosphorus are implanted into intermediate impurity region 17, thereby forming source region 14 having n type conductivity and formed to surround intermediate impurity region 17 (see FIG. 21). Next, for example, a p type impurity such as aluminum is further implanted into intermediate impurity region 17, thereby forming contact region 18 that is surrounded by intermediate impurity region 17, that extends from first main surface 10a to body region 13 in the normal direction of first main surface 10a of silicon carbide substrate 10, and that has p type conductivity. Contact region 18 is formed to be separated from source region 14 by intermediate impurity region 17 and body region 13 (see FIG. 22). Although it has been illustrated that contact region 18 is formed after source region 14 is formed, source region 14 may be formed after contact region 18 is formed.

Next, in order to activate the impurities provided in silicon carbide substrate 10 by the ion implantation, heat treatment (activation annealing) is performed. The activation annealing is preferably performed at a temperature of not less than 1500° C. and not more than 1900° C., for example, a temperature of approximately 1700° C. The activation annealing is performed for approximately 30 minutes, for example. The atmosphere of the activation annealing is preferably an inert gas atmosphere, such as an Ar atmosphere.

Next, a trench forming step is performed. For example, a mask layer 90 having an opening is formed on first main surface 10a including source region 14, intermediate impurity region 17, and contact region 18. As mask layer 90, a silicon oxide film or the like can be used, for example. The opening is formed to correspond to the location of trench TR (FIG. 18).

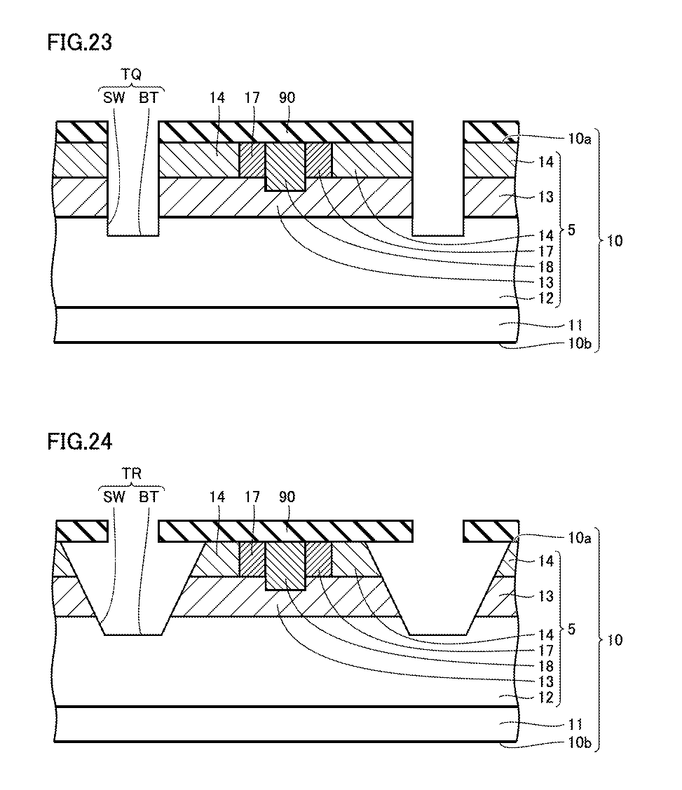

As shown in FIG. 23, in the opening of mask layer 90, source region 14, body region 13, and a portion of drift region 12 are removed by etching. An exemplary, usable etching method is reactive ion etching, in particular, inductively coupled plasma reactive ion etching (ICP-RIE). Specifically, ICP-RIE can be employed which uses SF₆ or a mixed gas of SF₆ and O₂ as a reactive gas, for example. By means of such etching, a recess TQ is formed which has a side portion SW and a bottom portion BT in a region in which trench TR is to be formed, side portion SW being substantially perpendicular to first main surface 10a, bottom portion BT being continuously connected to side portion SW and substantially parallel to first main surface 10a.

Next, thermal etching is performed in recess TQ. The thermal etching can be performed by, for example, heating in an atmosphere containing reactive gas having at least one or more types of halogen atom. The at least one or more types of halogen atom include at least one of chlorine (Cl) atom and fluorine (F) atom. This atmosphere is, for example, Cl₂, BCL₃, SF₆, or CF₄. For example, the thermal etching is performed using a mixed gas of chlorine gas and oxygen gas as a reactive gas, at a heat treatment temperature of, for example, not less than 700° C. and not more than 1000° C.

It should be noted that the reactive gas may contain a carrier gas in addition to the chlorine gas and the oxygen gas. An exemplary, usable carrier gas is nitrogen (N₂) gas, argon gas, helium gas, or the like. When the heat treatment temperature is set at not less than 700° C. and not more than 1000° C. as described above, a rate of etching SiC is approximately, for example, 70 μm/hour. In addition, during the thermal etching, mask layer 90, which is formed of silicon oxide and therefore has a very large selection ratio relative to SiC, is not substantially etched during the etching of SiC.

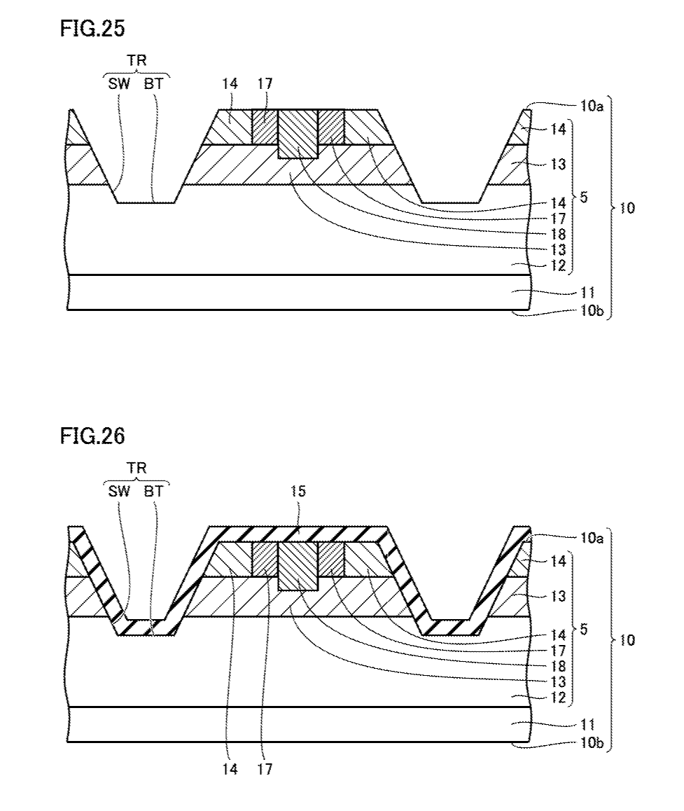

As shown in FIG. 24, by the thermal etching, trench TR is formed in first main surface 10a of silicon carbide substrate 10. Trench TR includes: side portion SW extending to drift region 12 through source region 14 and body region 13; and bottom portion BT located on drift region 12. When each of source region 14, body region 13, and drift region 12 is thermally etched to form side portion SW of trench TR, mask layer 90 is not substantially etched, with the result that mask layer 90 is left to project from first main surface 10a over side portion SW of trench TR. Next, mask layer 90 is removed by means of an appropriate method such as etching (see FIG. 25).

Next, a gate insulating film forming step is performed. Preferably, gate oxide film 15 is formed by thermally oxidizing silicon carbide substrate 10 having trench TR formed therein. Specifically, silicon carbide substrate 10 having trench TR formed therein is heated at, for example, about 1300° C. in an atmosphere containing oxygen, thereby forming gate oxide film 15. Gate oxide film 15 is formed to cover side portion SW and bottom portion BT of trench TR and cover first main surface 10a (see FIG. 26).

After thermally oxidizing silicon carbide substrate 10, heat treatment (NO annealing) may be performed onto silicon carbide substrate 10 in a nitrogen monoxide (NO) gas atmosphere. In the NO annealing, silicon carbide substrate 10 is held for about 1 hour at a temperature of not less than 1100° C. and not more than 1300° C. Accordingly, nitrogen atoms are introduced in an interface region between gate oxide film 15 and body region 13. As a result, formation of interface states in the interface region is suppressed, thereby achieving improved channel mobility. It should be noted that a gas other than the NO gas can be employed as the atmospheric gas as long as the nitrogen atoms can be thus introduced. After the NO annealing, Ar annealing may be further performed using argon (Ar) as an atmospheric gas. The Ar annealing is preferably performed at a heating temperature equal to or higher than the heating temperature in the above-described NO annealing and lower than the melting point of gate oxide film 15. This heating temperature is kept for approximately 1 hour, for example. Accordingly, formation of interface states in the interface region between gate oxide film 15 and body region 13 is further suppressed.

Next, a gate electrode forming step is performed. Gate electrode 27 is formed in contact with gate oxide film 15 in trench TR. Gate electrode 27 is disposed in trench TR, and is formed to face each of side portion SW and bottom portion BT of trench TR with gate oxide film 15 being interposed therebetween. Gate electrode 27 is formed, for example, by the LPCVD method. Next, for example, interlayer insulating film 21 made of a material containing silicon dioxide is formed in contact with each of gate electrode 27 and gate oxide film 15. Interlayer insulating film 21 is formed to fill a groove formed by gate electrode 27 formed in trench TR.

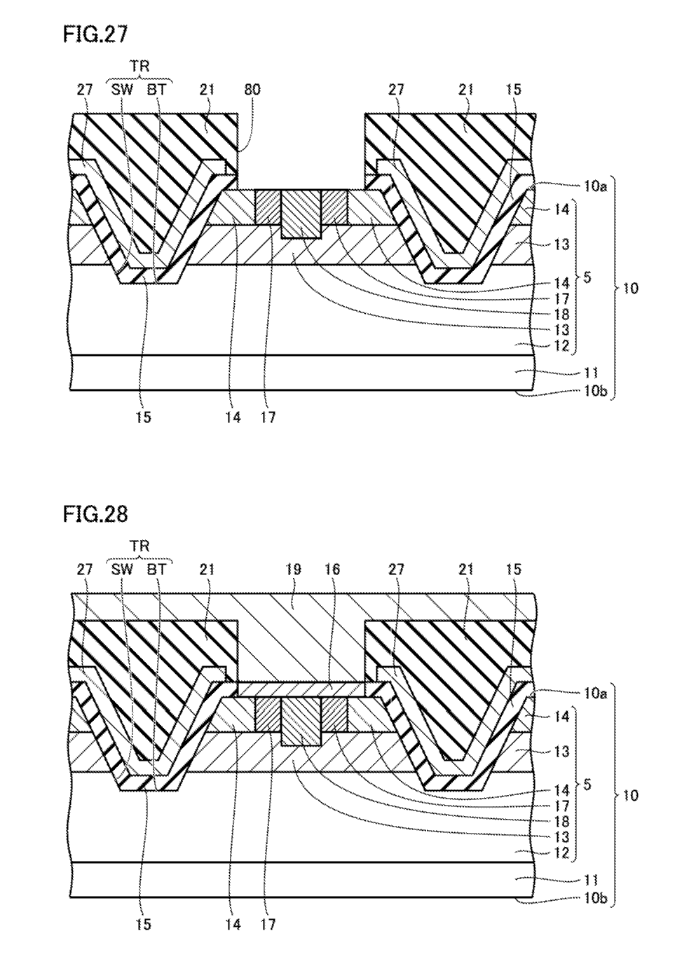

Next, a source electrode forming step is performed. With reference to FIG. 27, etching is performed to form opening 80 in interlayer insulating film 21 and gate oxide film 15. Each of source region 14, intermediate impurity region 17, and contact region 18 is exposed at first main surface 10a of silicon carbide substrate 10 by opening 80. Next, source electrode 16 is formed on first main surface 10a in contact with each of source region 14, intermediate impurity region 17, and contact region 18. Source electrode 16 is made of, for example, a material containing Ti, Al or Ni, preferably, is made of TiAlSi.

Next, source electrode 16 in contact with each of source region 14, intermediate impurity region 17, and contact region 18 is held for about 5 minutes at a temperature of not less than 900° C. and not more than 1100° C., for example. Accordingly, at least a portion of source electrode 16 reacts with silicon in silicon carbide substrate 10 to result in silicidation, and is accordingly alloyed. In this way, source electrode 16 in ohmic junction with source region 14 is formed. Preferably, both contact region 18 and source region 14 are in ohmic junction with source electrode 16. Next, front surface protecting electrode 19 is formed in contact with source electrode 16 to cover interlayer insulating film 21 (see FIG. 28). Next, drain electrode 20 is formed in contact with second main surface 10b of silicon carbide substrate 10. Next, backside surface protecting electrode 23 is formed in contact with drain electrode 20. In this way, trench type MOSFET 1 (FIG. 18) is completed.

Next, the following describes function and effect of trench type MOSFET 1 serving as the silicon carbide semiconductor device according to the third embodiment.

In accordance with trench type MOSFET 1 according to the third embodiment, main surface 10a of silicon carbide substrate 10 corresponds to a carbon plane or a plane off by 8° or less relative to the carbon plane. Accordingly, the on-resistance of the silicon carbide semiconductor device can be reduced.

In accordance with the method for manufacturing trench type MOSFET 1 according to the third embodiment, main surface 10a of silicon carbide substrate 10 corresponds to a carbon plane or a plane off by 8° or less relative to the carbon plane. Accordingly, the on-resistance of the silicon carbide semiconductor device can be reduced.

### Fourth Embodiment

Next, the following describes a configuration of a trench type MOSFET serving as a silicon carbide semiconductor device according to a fourth embodiment of the present invention. The trench type MOSFET according to the fourth embodiment is different from the trench type MOSFET according to the third embodiment in that intermediate impurity region 17 constitutes a portion of the second impurity region, and is the same as the trench type MOSFET according to the third embodiment in terms of other configurations. Hence, the same or corresponding portions are given the same reference characters and are not described repeatedly.

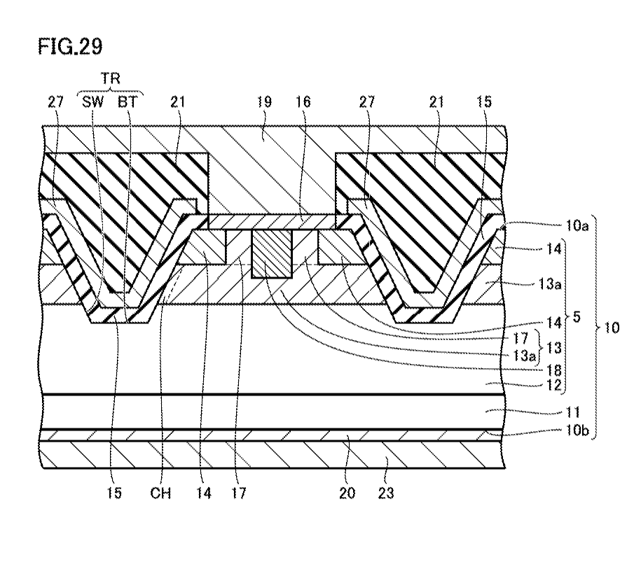

With reference to FIG. 29, intermediate impurity region 17 between source region 14 and contact region 18 constitutes a portion of body region 13. In other words, body region 13 includes: intermediate impurity region 17 in contact with source electrode 16 on first main surface 10a of silicon carbide substrate 10; and body region portion 13a continuously connected to intermediate impurity region 17. Body region portion 13a is in contact with contact region 18 and source region 14. The depth of contact region 18 may be larger than the depth of source region 14.

Each of body region portion 13a, source region 14, intermediate impurity region 17, and contact region 18 contains a p type impurity (first p type impurity) such as aluminum, for example. The concentration of the p type impurity (second p type impurity) in intermediate impurity region 17 is as large as the concentration of the p type impurity (second p type impurity) in body region portion 13a. In addition to the first p type impurity, contact region 18 contains a second p type impurity. Source region 14 contains the first n type impurity. That is, source region 14 includes the first p type impurity and the first n type impurity. The concentration of the p type impurity in intermediate impurity region 17 is lower than the concentration of the p type impurity in contact region 18 and is lower than the concentration of the n type impurity in source region 14.

It should be noted that in each of the embodiments described above, it has been illustrated the first conductivity type is n type and the second conductivity type is p type, but the first conductivity type may be p type and the second conductivity type may be n type. Although the MOSFET has been illustrated as an exemplary silicon carbide semiconductor device, the silicon carbide semiconductor device may be an IGBT (Insulated Gate Bipolar Transistor). When the silicon carbide semiconductor device is an IGBT, an emitter electrode may be used instead of the source electrode, and a collector electrode may be used instead of the drain electrode.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device comprising:
a silicon carbide substrate having a main surface, said silicon carbide substrate including a first impurity region, a second impurity region, a third impurity region, a fourth impurity region, and an intermediate impurity region, said first impurity region having first conductivity type, said second impurity region being in contact with said first impurity region and having second conductivity type different from said first conductivity type, said third impurity region having said first conductivity type and being separated from said first impurity region by said second impurity region, said fourth impurity region having said second conductivity type and connecting said main surface and said second impurity region to each other, said intermediate impurity region being interposed between said third impurity region and said fourth impurity region and having an impurity concentration that is lower than a concentration of a first conductivity type impurity in said third impurity region and that is lower than a concentration of a second conductivity type impurity in said fourth impurity region; and
an electrode in contact with each of said third impurity region and said fourth impurity region on said main surface of said silicon carbide substrate,
the concentration of said first conductivity type impurity in said third impurity region in contact with said electrode being not less than 5×10¹⁹ cm⁻³.

2. The silicon carbide semiconductor device according to claim 1, wherein the concentration of said second conductivity type impurity in said fourth impurity region in contact with said electrode is not less than 5×10¹⁹ cm⁻³.

3. The silicon carbide semiconductor device according to claim 1, wherein the concentration of said first conductivity type impurity or the concentration of said second conductivity type impurity in said intermediate impurity region in contact with said electrode is not less than 1×10¹⁸ cm⁻³ and less than 5×10¹⁹ cm⁻³.

4. The silicon carbide semiconductor device according to claim 1, wherein said electrode contains at least one of Ti, Al and Ni.

5. The silicon carbide semiconductor device according to claim 4, wherein said electrode contains TiAlSi.

6. The silicon carbide semiconductor device according to claim 1, wherein said first conductivity type is n type, and said second conductivity type is p type.

7. The silicon carbide semiconductor device according to claim 1, wherein said intermediate impurity region constitutes a portion of said second impurity region.

8. The silicon carbide semiconductor device according to claim 1, wherein
said main surface of said silicon carbide substrate corresponds to a silicon plane or a plane off by 8° or less relative to the silicon plane, and
the silicon carbide semiconductor device includes a planar type MOSFET.

9. The silicon carbide semiconductor device according to claim 1, wherein
said main surface of said silicon carbide substrate corresponds to a carbon plane or a plane off by 8° or less relative to the carbon plane, and
the silicon carbide semiconductor device includes a trench type MOSFET.

10. A method for manufacturing a silicon carbide semiconductor device, comprising the steps of:
forming a silicon carbide substrate having a main surface, said silicon carbide substrate including a first impurity region, a second impurity region, a third impurity region, a fourth impurity region, and an intermediate impurity region, said first impurity region having first conductivity type, said second impurity region being in contact with said first impurity region and having second conductivity type different from said first conductivity type, said third impurity region having said first conductivity type and being separated from said first impurity region by said second impurity region, said fourth impurity region having said second conductivity type and connecting said main surface and said second impurity region to each other, said intermediate impurity region being interposed between said third impurity region and said fourth impurity region and having an impurity concentration that is lower than a concentration of a first conductivity type impurity in said third impurity region and that is lower than a concentration of a second conductivity type impurity in said fourth impurity region; and
forming an electrode in contact with each of said third impurity region and said fourth impurity region on said main surface of said silicon carbide substrate,
the concentration of said first conductivity type impurity in said third impurity region in contact with said electrode being not less than 5×10¹⁹ cm⁻³.

11. The method for manufacturing the silicon carbide semiconductor device according to claim 10, wherein
the step of forming said silicon carbide substrate includes the steps of
forming said first impurity region,
forming said second impurity region by introducing said second conductivity type impurity into said first impurity region,
forming said intermediate impurity region by introducing said first conductivity type impurity or said second conductivity type impurity into said second impurity region,
forming said fourth impurity region by introducing said second conductivity type impurity into said intermediate impurity region, and
forming said third impurity region by introducing said first conductivity type impurity into said intermediate impurity region.

12. The method for manufacturing the silicon carbide semiconductor device according to claim 10, wherein
the step of forming said silicon carbide substrate includes the steps of
forming said first impurity region,
forming said second impurity region by introducing said second conductivity type impurity into said first impurity region, and
forming each of said third impurity region and said fourth impurity region such that said third impurity region is separated from said fourth impurity region, by introducing said first conductivity type impurity and said second conductivity type impurity into said second impurity region, and
said intermediate impurity region constitutes a portion of said second impurity region.

13. The method for manufacturing the silicon carbide semiconductor device according to claim 10, wherein each of said third impurity region and said fourth impurity region is formed by ion implantation.

14. The method for manufacturing the silicon carbide semiconductor device according to claim 10, wherein the concentration of said second conductivity type impurity in said fourth impurity region in contact with said electrode is not less than 5×10¹⁹ cm⁻³.

15. The method for manufacturing the silicon carbide semiconductor device according to claim 10, wherein the concentration of said first conductivity type impurity or the concentration of said second conductivity type impurity in said intermediate impurity region in contact with said electrode is not less than 1×10¹⁸ cm⁻³ and less than 5×10¹⁹ cm⁻³.

16. The method for manufacturing the silicon carbide semiconductor device according to claim 10, wherein said electrode contains at least one of Ti, Al and Ni.

17. The method for manufacturing the silicon carbide semiconductor device according to claim 16, wherein said electrode contains TiAlSi.

18. The method for manufacturing the silicon carbide semiconductor device according to claim 10, wherein said first conductivity type is n type and said second conductivity type is p type.

19. The method for manufacturing the silicon carbide semiconductor device according to claim 10, wherein
said main surface of said silicon carbide substrate corresponds to a silicon plane or a plane off by 8° or less relative to the silicon plane, and
the silicon carbide semiconductor device includes a planar type MOSFET.

20. The method for manufacturing the silicon carbide semiconductor device according to claim 10, wherein
said main surface of said silicon carbide substrate corresponds to a carbon plane or a plane off by 8° or less relative to the carbon plane, and
the silicon carbide semiconductor device includes a trench type MOSFET.
